(19) United States
(12) Patent Application Publication
(10) Pub. No.: US 2026/0144059 A1
(43) Pub. Date: May 21, 2026

(54) SEMICONDUCTOR PACKAGE AND METHOD OF MANUFACTURING THE SAME

(71) Applicant: Samsung Electronics Co., Ltd., Suwon-si (KR)

(72) Inventor: Soohyun Kim, Suwon-si (KR)

(21) Appl. No.: 19/331,014

(22) Filed: Sep. 17, 2025

(30) Foreign Application Priority Data
Nov. 15, 2024 (KR) 10-2024-0163365

(51) Int. Cl. H01L 23/367; H01L 21/48; H01L 21/56; H01L 23/00; H01L 23/31; H01L 23/373; H01L 23/538; H01L 25/18; H10B 80/00; H10D 80/30

(52) U.S. Cl. CPC H10W 40/22; H10W 40/037; H10W 40/258; H10W 70/611; H10W 70/65; H10W 74/014; H10W 74/019; H10W 74/141; H10W 90/00; H10B 80/00; H10D 80/30; H10W 72/0198; H10W 74/15; H10W 90/724; H10W 90/734; H10W 90/736

(57) ABSTRACT

Provided are a semiconductor package including semiconductor devices sealed on an interposer and capable of improving heat dissipation characteristics and warpage, and a method of manufacturing the semiconductor package. The semiconductor package includes an interposer, a first semiconductor device arranged on the interposer, a second semiconductor device spaced apart from the first semiconductor device on the interposer, and a heat dissipation plate arranged on upper surfaces of the first semiconductor device and the second semiconductor device and having a dam arranged in an edge portion thereof.

### CROSS-REFERENCE TO RELATED APPLICATION

This application is based on and claims priority under 35 U.S.C. §119 to Korean Patent Application No. 10-2024-0163365, filed on Nov. 15, 2024, in the Korean Intellectual Property Office, the disclosure of which is incorporated by reference herein in its entirety.

### BACKGROUND

The inventive concept relates to a semiconductor package, and more particularly, to a semiconductor package including a structure in which semiconductor chips are stacked, and a method of manufacturing the same.

In accordance with the rapid development of the electronics industry and the needs of users, electronic devices are becoming more compact and lightweight. Accordingly, semiconductor packages used in electronic devices are also becoming more compact and lightweight. In addition, semiconductor packages require high reliability along with high performance and large capacity. To implement miniaturization, weight reduction, high performance, large capacity, and high reliability, research and development has been continuously conducted into semiconductor chips including a through silicon via (TSV) structure and semiconductor packages having a chip stack structure in which the semiconductor chips are stacked.

### SUMMARY

Aspects of the inventive concept provide a chip-type semiconductor package including semiconductor devices sealed on an interposer and capable of improving heat dissipation characteristics and warpage, and a method of manufacturing the semiconductor package.

In addition, the inventive concept is not limited to those described above, and other aspects that are not described herein will be clearly understood from the following description by those of ordinary skill in the art.

According to an aspect of the inventive concept, there is provided a semiconductor package including an interposer, a first semiconductor device arranged on the interposer, a second semiconductor device spaced apart from the first semiconductor device on the interposer, and a heat dissipation plate arranged on upper surfaces of the first semiconductor device and the second semiconductor device and having a dam arranged in an edge portion of the heat dissipation plate.

According to another aspect of the inventive concept, there is provided a semiconductor package including a package substrate, a chip package arranged on the package substrate, and a heat dissipation structure arranged on the chip package, wherein the chip package includes an interposer, a first semiconductor device arranged on the interposer, a second semiconductor device arranged on the interposer and spaced apart from the first semiconductor device, an intermediate heat dissipation plate arranged on upper surfaces of the first semiconductor device and the second semiconductor device and having a dam arranged along an edge portion thereof, and a sealant arranged between the interposer and the intermediate heat dissipation plate and sealing the first semiconductor device and the second semiconductor device.

According to another aspect of the inventive concept, there is provided a semiconductor package including a package substrate, a chip package arranged on the package substrate, a heat dissipation structure arranged on the chip package, and a thermal interface material (TIM) arranged between the chip package and the heat dissipation structure, wherein the chip package includes an interposer, a first semiconductor device arranged on the interposer, a second semiconductor device spaced apart from the first semiconductor device on the interposer, and an intermediate heat dissipation plate arranged on upper surfaces of the first semiconductor device and the second semiconductor device and having a dam surrounding the TIM in an edge portion of the intermediate heat dissipation plate.

### BRIEF DESCRIPTION OF THE DRAWINGS

Embodiments will be more clearly understood from the following detailed description taken in conjunction with the accompanying drawings in which:

FIG. 1 is a cross-sectional view of a semiconductor package according to an embodiment;

FIGS. 2A to 2C are conceptual diagrams each illustrating a shape of a dam on an upper surface of an intermediate heat dissipation plate in the semiconductor package of FIG. 1;

FIGS. 3A to 3C are respectively a conceptual diagram and photographs illustrating defects in a semiconductor package of a comparative example;

FIGS. 4A to 4C are cross-sectional views each illustrating a structure of a first semiconductor device in the semiconductor package of FIG. 1;

FIGS. 5A to 5D are cross-sectional views of semiconductor packages according to embodiments;

FIGS. 6A and 6B are cross-sectional views of system packages according to embodiments;

FIGS. 7A and 7B are respectively a perspective view and a cross-sectional view of a system package according to an embodiment;

FIGS. 8A and 8B are cross-sectional views of system packages according to embodiments;

FIGS. 9A to 9I are cross-sectional views schematically illustrating a method of manufacturing a system package, according to an embodiment; and

FIGS. 10A to 10C are cross-sectional views illustrating in more detail a process of manufacturing a first package structure of FIG. 9A.

### DETAILED DESCRIPTION OF THE EMBODIMENTS

Hereinafter, embodiments will be described in detail with reference to the accompanying drawings. The same elements in the drawings are denoted by the same reference numerals, and redundant descriptions thereof are omitted.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” or “electrically coupled” are configured such that an electrical signal can be transferred from one component to the other (although such electrical signal may be attenuated in strength as it is transferred and may be selectively transferred).

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

Terms such as “same,” “equal,” “planar,” “coplanar,” “parallel,” “uniform,” and “perpendicular,” as used herein encompass identicality or near identicality including variations that may occur, for example, due to manufacturing processes. The term “substantially” may be used herein to emphasize this meaning, unless the context or other statements indicate otherwise.

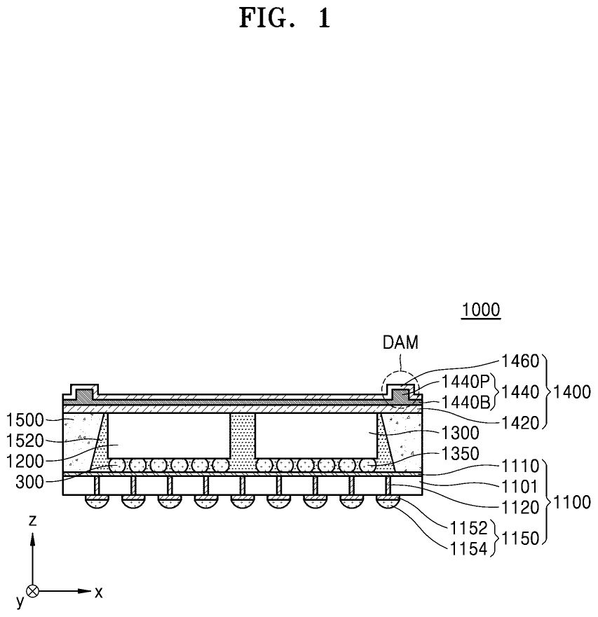

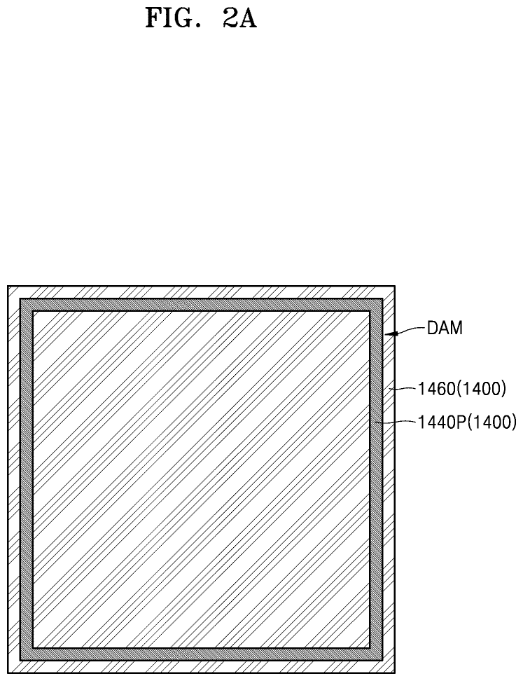

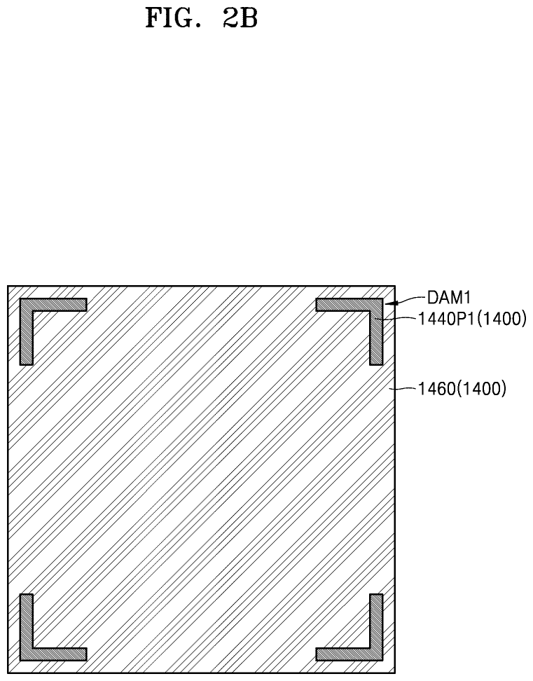

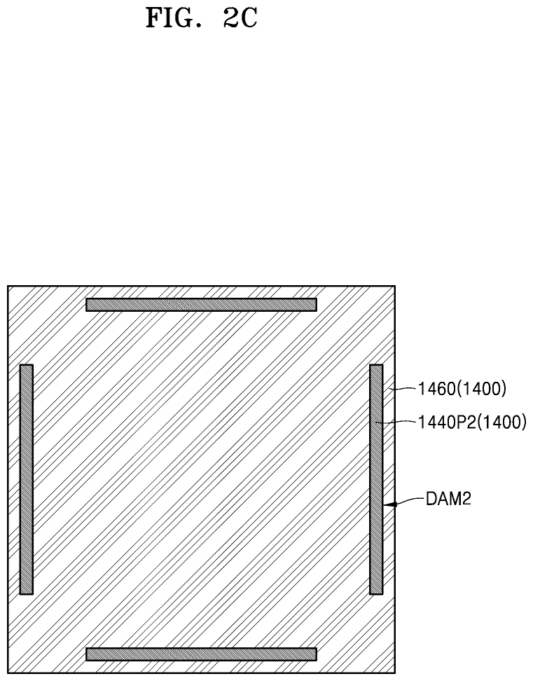

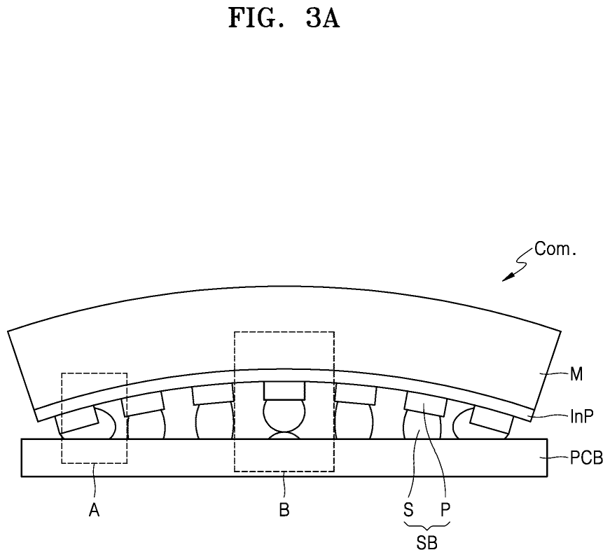

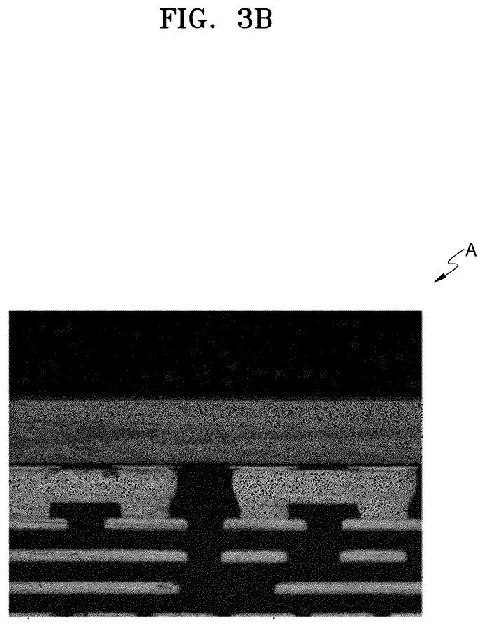

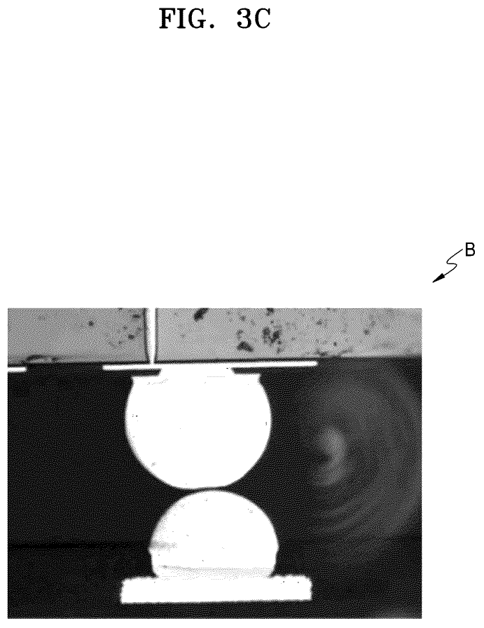

FIG. 1 is a cross-sectional view of a semiconductor package according to an embodiment, and FIGS. 2A to 2C are conceptual diagrams each illustrating a shape of a dam on an upper surface of an intermediate heat dissipation plate in the semiconductor package of FIG. 1. FIGS. 3A to 3C are respectively a conceptual diagram and photographs illustrating defects in a semiconductor package of a comparative example.

Referring to FIGS. 1 to 2C, a semiconductor package 1000 of the present embodiment may include an interposer 1100, a first semiconductor device 1200, a second semiconductor device 1300, an intermediate heat dissipation plate 1400, and a sealant 1500.

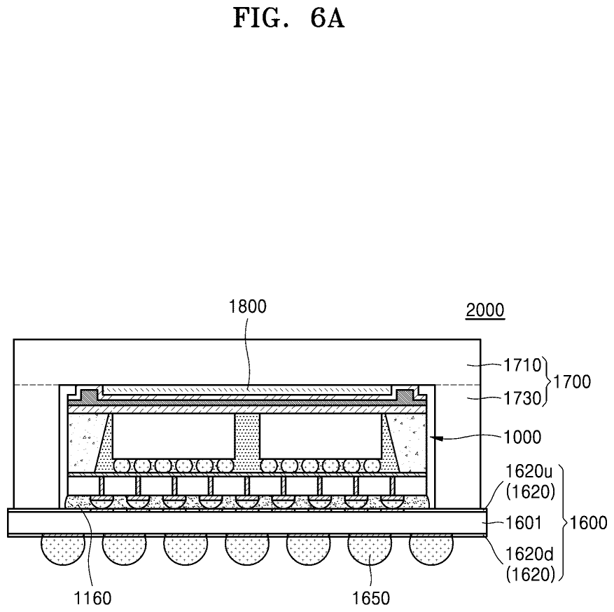

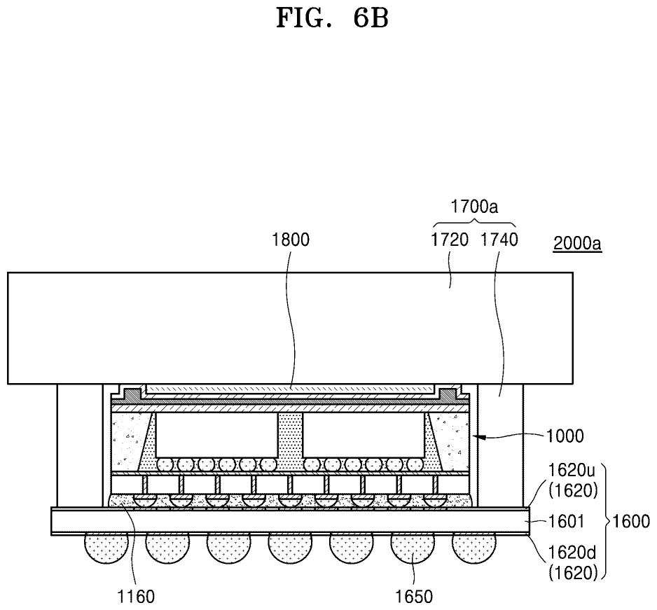

The interposer 1100 may mediate signal transmission or transfer signals between the first semiconductor device 1200 and the second semiconductor device 1300. For example, the first semiconductor device 1200 and the second semiconductor device 1300 may be mounted on the interposer 1100 and electrically connected to each other through the interposer 1100. In addition, the interposer 1100 may mediate the transmission of signals, power, or the like between the first semiconductor device 1200 and a package substrate (see 1600 of FIG. 6A) and between the second semiconductor device 1300 and the package substrate 1600. For example, the interposer 1100 may be mounted on the package substrate 1600 and may electrically connect the first semiconductor device 1200 and the second semiconductor device 1300 to the package substrate 1600.

The interposer 1100 may include a body layer 1101, a wiring layer 1110, a through electrode 1120, and a first external connection terminal 1150. The body layer 1101 may include, for example, silicon (Si). Accordingly, the interposer 1100 may be a Si-interposer. However, the interposer 1100 is not limited to a Si interposer.

The wiring layer 1110 may be arranged on the body layer 1101 and may include an interlayer insulating layer and wirings. The wirings may electrically connect the first semiconductor device 1200 to the second semiconductor device 1300. In addition, the wirings may electrically connect the through electrode 1120 to a pad on the interposer 1100.

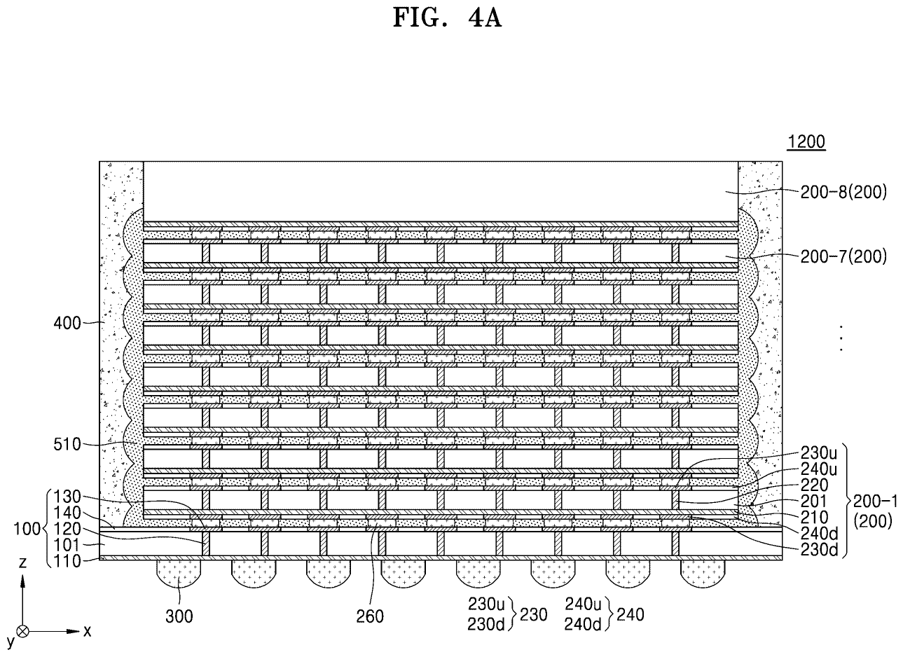

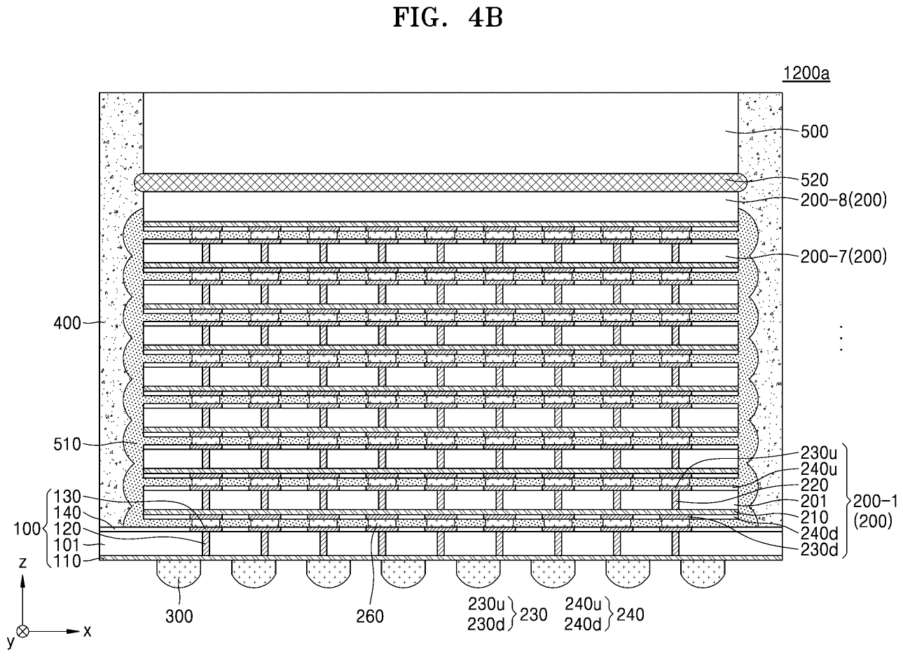

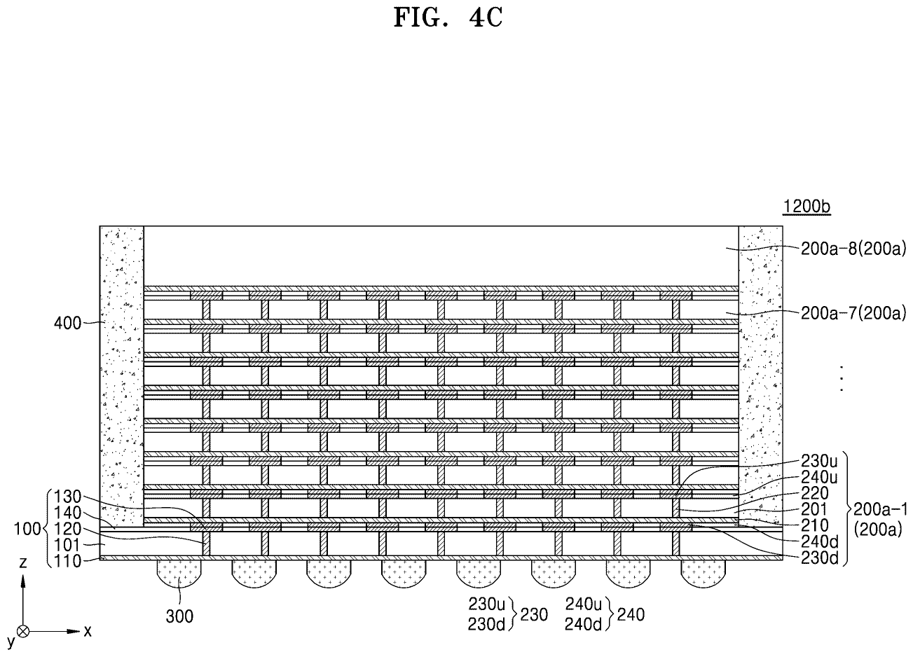

The through electrode 1120 may extend lengthwise in a vertical direction to pass through the body layer 1101. Because the body layer 1101 includes Si, the through electrode 1120 may be a through silicon via (TSV). The through electrode 1120 may extend to the inside of the wiring layer 1110 and may be electrically connected to the wirings of the wiring layer 1110. For example, the through electrode 1120 may overlap the wiring layer 1110 in a horizontal direction. In addition, the through electrode 1120 may be electrically connected to the first external connection terminal 1150 through a pad on a lower surface of the interposer 1100. A specific structure of the through electrode 1120 is described in more detail in the description of the first semiconductor device 1200 of FIG. 4A.

The first external connection terminal 1150 may be arranged on the pad on the lower surface of the interposer 1100. The first external connection terminal 1150 may be electrically connected to the through electrode 1120 through the pad. The first external connection terminal 1150 may include a pillar 1152 and a solder 1154. In some embodiments, the first external connection terminal 1150 may include only the solder 1154. For example, the first external connection terminal 1150 may be formed of the solder 1154.

The pillar 1152 may include, for example, nickel (Ni), copper (Cu), palladium (Pd), platinum (Pt), gold (Au) or any combination thereof. In some embodiments, the pillar 1152 may act as a pad and may include Cu. Accordingly, the pillar 1152 may be a bump pad, a Cu-pad, or a Cu-pillar. In certain embodiments, when the pillar 1152 acts as a pad, a separate pad may not be formed on the lower surface of the interposer 1100. For example, the pad and the pillar 1152 may be integrally formed as one body in certain embodiments.

The solder 1154 may be arranged on the pillar 1152. The solder 1154 may include tin (Sn), indium (In), bismuth (Bi), antimony (Sb), copper (Cu), silver (Ag), zinc (Zn), and/or any alloy thereof. For example, the solder 1154 may include Sn, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, or the like. In some embodiments, the solder 1154 may be a bump or a solder bump.

In the semiconductor package 1000 of the present embodiment, the interposer 1100 may be a 2.5D interposer. However, the interposer 1100 is not limited to a 2.5D interposer. For example, the interposer 1100 may be a 2.3D interposer. For reference, the interposer may include a 2.5D interposer and a 2.3D interposer. In addition, in some embodiments, interposers may be sub-divided based on structures of interposers, e.g., including a Si-bridge. Accordingly, interposers other than the 2.5D interposer may be referred to as 2.xD interposers.

The 2.5D interposer may be a Si interposer and may include a TSV therein. The 2.3D interposer may be an organic or inorganic interposer. The organic interposer may use polyimide (PI), benzocyclobutene (BCB), and polybenzoxazole (PBO) as the body layer, and the inorganic interposer may use ceramic or glass as the body layer. When the 2.3D interposer includes a through electrode, the through electrode may be a through dielectric via (TDV), or a through glass via (TGV) according to the material of the body layer. In some embodiments, the 2.3D interposer may be a panel level package (PLP) interposer, or a re-distribution layer (RDL) interposer.

The first semiconductor device 1200 may be mounted on the interposer 1100 through first connection terminals 300. FIG. 1 shows that the first semiconductor device 1200 is arranged on the left side of the interposer 1100 in an x direction. However, the position of the first semiconductor device 1200 is not limited thereto.

The first semiconductor device 1200 may include memory devices. For example, the first semiconductor device 1200 may include a volatile memory device, such as dynamic random access memory (DRAM) or static random access memory (SRAM), or a non-volatile memory device, such as flash memory, phase-change random access memory (PRAM), magnetoresistive random access memory (MRAM), ferroelectric random access memory (FeRAM), or resistive random access memory (RRAM). In addition, when the first semiconductor device 1200 includes memory devices, the first semiconductor device 1200 may have a single chip structure or a package structure. In the semiconductor package 1000 of the present embodiment, the first semiconductor device 1200 may include, for example, a high bandwidth memory (HBM) package. The HBM package structure of the first semiconductor device 1200 is described in more detail with reference to FIGS. 4A to 4C. Throughout the present application, a structure of an element or a device, or an element structure or a device structure may be the element or device itself or a device or an element having substantially the same structure as the device or element. For example, when a wafer or a substrate has a chip structure or a package structure, the wafer or substrate may include the same structure as the chip or the package except singulation (e.g., except the outer shape of the chip/package). For example, a chip structure may include all inside structure of a chip, and a package structure may include all inside structure of a package. As another example, when a substrate or wafer includes a chip/package structure, the substrate/wafer may include a plurality of chips/packages in it.

The first semiconductor device 1200 is not limited to the HBM package. For example, the first semiconductor device 1200 may have a general package structure. In the general package structure, the first semiconductor device 1200 may include an upper package substrate and a plurality of memory chips stacked on the upper package substrate. In addition, the memory chips may be stacked on the upper package substrate and may be electrically connected to the upper package substrate and/or to each other through bonding wires, or may be stacked on the upper package substrate and may be electrically connected to the upper package substrate through bumps and TSVs.

The second semiconductor device 1300 may be mounted on the interposer 1100 through second connection terminals 1350. FIG. 1 shows that the second semiconductor device 1300 may be arranged adjacent to and/or spaced apart from the first semiconductor device 1200 on the right side of the interposer 1100 in the x direction. However, the position of the second semiconductor device 1300 is not limited thereto. For example, the first semiconductor device 1200 may be arranged on the right side of the interposer 1100 in the x direction, and the second semiconductor device 1300 may be arranged on the left side of the interposer 1100 in the x direction.

The second semiconductor device 1300 may have a chip or package structure. In the semiconductor package 1000 of the present embodiment, the second semiconductor device 1300 may have a chip structure. For example, the second semiconductor device 1300 may include a logic chip. Accordingly, the second semiconductor device 1300 may include a plurality of logic devices therein. The logic devices may include, for example, an AND, a NAND, an OR, NOR, an exclusive OR (XOR), an exclusive NOR (XNOR), an inverter (INV), an adder (ADD), a delay (DLY), a filter (FIL), a multiplexer (MXT/MXIT), an OR/AND/INV (OAI), an AND/OR (AO), an AND/OR/INV (AOI), a D flip-flop, a reset flip-flop, a master-slave flip-flop, a latch, a counter, or buffer devices. The logic devices may perform a variety of signal processing, such as analog signal processing, analog-to-digital (A/D) conversion, or control. The second semiconductor device 1300 may be a central processing unit (CPU) chip, a micro-processor unit (MPU) chip, a graphics processing unit (GPU) chip, a neural processing unit (NPU) chip, a system on glass (SOG) chip, an application specific integrated circuit (ASIC) chip, an application processor (AP) chip, or a control chip, and may have a corresponding function thereof.

In the semiconductor package 1000 of the present embodiment, the second semiconductor device 1300 may have a chip structure, a system on chip (SoC) structure, or a chiplet structure. The SoC structure may have a structure in which a plurality of systems are integrated into a single chip. Accordingly, the second semiconductor device 1300 having the SoC structure may perform computational functions, data storage, analog and digital signal conversion, and the like in a single chip. On the other hand, the chiplet structure may have a structure in which a logic chip is divided into separate chips for each function and the respective chips are electrically connected to each other. The second semiconductor device 1300 having the chiplet structure may overcome the performance limit of a single chip.

In certain embodiments, the second semiconductor device 1300 may include communication support devices. However, in some embodiments, the communication support devices may be separately provided as other chips, for example, modem chips, and may be arranged on the interposer 1100 in a structure electrically coupled to the second semiconductor device 1300.

The second semiconductor device 1300 may include a chip body and an active layer. The chip body may constitute a body of the second semiconductor device 1300 and may include Si. However, the material of the chip body is not limited to Si. For example, the chip body may include other semiconductor materials, such as germanium (Ge) or Si—Ge, or a Group III-V compound, such as GaP, GaAs, or GaSb.

The active layer may be arranged below the chip body and may include an integrated circuit layer and a wiring layer. The integrated circuit layer may include a plurality of integrated devices. The plurality of integrated devices may include, for example, the logic devices described above. The wiring layer may be arranged below the integrated circuit layer. The wiring layer may include an interlayer insulating layer and wirings. The wirings may be arranged in two or more layers, and the wirings in different layers may be electrically connected to each other through vertical vias.

A lower surface of the second semiconductor device 1300 may be a front surface, which is an active surface, and an upper surface of the second semiconductor device 1300 may be a back surface, which is an inactive surface. For example, a lower side or a bottom surface of the chip body on which the wiring layer is arranged may correspond to or may be the front surface of the second semiconductor device 1300, and an upper side or an upper surface of the chip body may correspond to or may be the back surface of the second semiconductor device 1300.

The intermediate heat dissipation plate 1400 may be arranged on the first semiconductor device 1200, the second semiconductor device 1300, and the sealant 1500. For example, the intermediate heat dissipation plate 1400 may completely cover the upper surfaces of the first semiconductor device 1200, the second semiconductor device 1300, and the sealant 1500. The intermediate heat dissipation plate 1400 may have a flat plate shape or a shape having a dam structure formed on a flat plate. For example, as illustrated in FIGS. 2A to 2C, the intermediate heat dissipation plate 1400 may have a shape having a dam formed on a rectangular flat plate, e.g., having a rectangular shape. For example, the flat plate may have a thickness less than 10% of both the width and length of the plate, and may have flat upper and lower surfaces that are parallel to each other.

The intermediate heat dissipation plate 1400 may include a lower metal layer 1420, an intermediate metal layer 1440, and an upper metal layer 1460. For example, the intermediate heat dissipation plate 1400 may be a heat dissipation plate. The layers of the intermediate heat dissipation plate 1400 may each include one of aluminum (Al), copper (Cu), tungsten (W), nickel (Ni), titanium (Ti), or gold (Au). However, the material of each of the layers of the intermediate heat dissipation plate 1400 is not limited to the materials described above. For example, the layers of the intermediate heat dissipation plate 1400 may each include various other metal materials that have high thermal conductivity (e.g., greater than 170 or greater than 200 watts per meter-kelvin (W·m⁻¹·K⁻¹) and are easy to manufacture.

The layers of the intermediate heat dissipation plate 1400 may each be formed through various processes, such as physical vapor deposition (PVD), chemical vapor deposition (CVD), or plating. In the case of the PVD, sputtering may be used. In the case of the plating, both electroplating and electroless plating may be used. For reference, the electroplating may be a process depositing a film of a metal onto a surface of another metal by using a principle of electrolysis and/or may be an electrochemical plating. The electroless plating may be a plating that does not use electrolysis. The electroless plating may be a process depositing a film by causing chemical reduction of metal ions on a surface of an object to be plated. The electroless plating may be a chemical plating.

FIG. 1 shows that the lower metal layer 1420 of the intermediate heat dissipation plate 1400 may have a flat plate shape with a uniform thickness. For example, the lower metal layer 1420 may have a rectangular flat plate shape. For example, the lower metal layer 1420 may be a flat plate, e.g., a rectangular flat plate.

The intermediate metal layer 1440 may include a base 1440B having a flat plate shape and a protrusion 1440P on the outer portion of the upper surface of the base 1140B. The base 1440B may have a rectangular flat plate shape, like the lower metal layer 1420. The protrusion 1440P may have various shapes on the upper surface of the base 1440B. For example, as illustrated in FIG. 2A, the protrusion 1440P may be arranged in a rectangular ring shape (e.g., a continuous rectangular ring shape) on the outer portion of the upper surface of the base 1440B. As illustrated in FIG. 2B, a protrusion 1440P1 may have an L-shape and may be arranged adjacent to each of four vertices of the upper surface of the base 1440B. As illustrated in FIG. 2C, a protrusion 1440P2 may have a straight line shape and may be arranged adjacent to each of four sides of the upper surface of the base 1440B. On the other hand, the shape of the protrusion 1440P is not limited to the three shapes described above. For example, the protrusion 1440P may have various shapes surrounding and/or along the outer portion of the upper surface of the base 1440B.

The upper metal layer 1460 may cover the intermediate metal layer 1440 with a uniform thickness. Accordingly, a portion of the upper metal layer 1460 corresponding to or contacting the base 1140B of the intermediate metal layer 1440 may have a flat plate shape, and a portion of the upper metal layer 1460 corresponding to or contacting the protrusion 1440P of the intermediate metal layer 1440 may have a protruding shape. The protrusion 1440P of the intermediate metal layer 1440 and the protruding portion of the upper metal layer 1460 covering the protrusion 1440P may form a dam DAM. In addition, the shape of the dam DAM may be determined according to the shape of the protrusion 1440P of the intermediate metal layer 1440. For example, as illustrated in FIG. 2A, when the protrusion 1440P has a rectangular ring shape, the dam DAM having a rectangular ring shape may be formed. As illustrated in FIG. 2B, when the protrusion 1440P1 has an L-shape, a dam DAM1 having an L-shape may be formed. As illustrated in FIG. 2C, when the protrusion 1440P2 has a straight line shape, a dam DAM2 having a straight line shape may be formed. For example, the upper metal layer 1460 may be conformally formed on the intermediate metal layer 1440 to completely overlap the intermediate metal layer 1440 in a vertical direction. For example, the dam DAM1 may include a plurality of discrete L-shaped portions, and each of the L-shaped portions may be arranged adjacent to a corresponding one of four vertices of a rectangular upper surface of the heat dissipation plate 1400. As another example, the dam DAM2 may include a plurality of linearly shaped portions, and each of the linearly shaped portions may extend along a corresponding one of four sides of a rectangular upper surface of the heat dissipation plate 1400.

For reference, in a structure in which the semiconductor package 1000 and a heat dissipation structure (see 1700 of FIG. 6A) are coupled to each other through a thermal interface material (TIM) (see 1800 of FIG. 6A), the dam DAM may surround the TIM 1800 and may prevent the TIM 1800 from being pumped out to the outside of the dam in a temperature cycling (TC) reliability test or the like. As a result, because the TIM 1800 is not pumped out and is maintained only inside the dam DAM of the intermediate heat dissipation plate 1400, the adhesive strength between the semiconductor package 1000 and the heat dissipation structure 1700 may be increased and the heat dissipation capability through the TIM 1800 may be improved. When the TIM 1800 is pumped out, the amount of the TIM 1800 remaining on the heat dissipation plate 1400 may be insufficient, and thus, the adhesive strength between the semiconductor package 1000 and the heat dissipation structure 1700 may be decreased. In addition, because a space therebetween is filled with an air layer as much as the TIM 1800 is pumped out, the heat dissipation capability through the TIM 1800 may also be decreased.

The semiconductor package 1000 may be mounted on the package substrate (see 1600 of FIG. 6A) through first external connection terminals 1150, and the adhesive strength between the heat dissipation structure 1700 and the semiconductor package 1000 may be increased, e.g., because the heat dissipation structure 1700 adheres to an upper surface of the package substrate. Accordingly, warpage of the semiconductor package 1000 may be improved and defects such as non-wet/short of the first external connection terminals 1150 may be improved.

Defects such as non-wet/short of the first external connection terminals 1150 are described briefly with reference to a semiconductor package Com. of a comparative example illustrated in FIGS. 3A to 3C. A chip-type package structure in which semiconductor devices (not shown) are mounted on an interposer InP and sealed with a sealant M may be a molded interposer (MIP) chip or a chip package. In the present disclosure, a chip-type package, a chip-type semiconductor package, or a chip package may be a package in which a semiconductor device/chip is mounted on an interposer and sealed with a sealant on the interposer. The chip package, the chip-type package, or the chip-type semiconductor package may include additional structure, e.g., multiple semiconductor chips/devices, a heat dissipater, an underfill layer, connection terminals, etc. The semiconductor package Com. of the comparative example having a chip package structure may be mounted on a package substrate PCB through external connection terminals SB. Each of the external connection terminals SB may include a pillar P and a solder S. In addition, although not illustrated, underfill may fill a gap between the semiconductor package Com. of the comparative example and the package substrate PCB.

A thermal expansion coefficient of the sealant M and/or the underfill may be greatly different from a thermal expansion coefficient of the interposer InP and/or the semiconductor devices of the semiconductor package Com. of the comparative example. Accordingly, as illustrated in FIG. 3A, warpage may occur in the semiconductor package Com. of the comparative example. Accordingly, a short-circuit defect may occur in which adjacent external connection terminals SB are electrically connected to each other at the outer portion of the interposer InP, and a non-wet defect may occur in which the external connection terminals SB are separated from the package substrate PCB or the interposer InP at the central portion of the interposer InP. For reference, FIGS. 3B and 3C are micrographs of cross-sections of regions A and B of FIG. 3A.

In contrast, the semiconductor package 1000 of the present embodiment may include the intermediate heat dissipation plate 1400, and the dam DAM may be formed on the upper surface of the intermediate heat dissipation plate 1400. Accordingly, in a structure in which the semiconductor package 1000 is mounted on the package substrate 1600 and coupled to the heat dissipation structure 1700 through the TIM 1800, the TIM 1800 may be surrounded by the dam DAM and maintained without being pumped out in the TC reliability test or another process, and thus, the adhesive strength to the heat dissipation structure 1700 may be increased and the warpage of the semiconductor package 1000 may be improved. As a result, due to the improvement in the warpage of the semiconductor package 1000, defects such as non-wet/short of the first external connection terminals 1150 may be significantly improved.

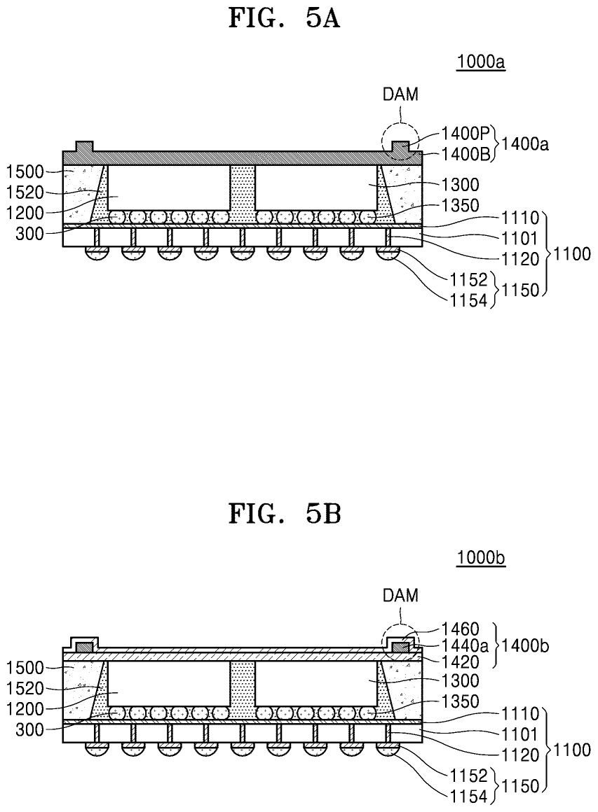

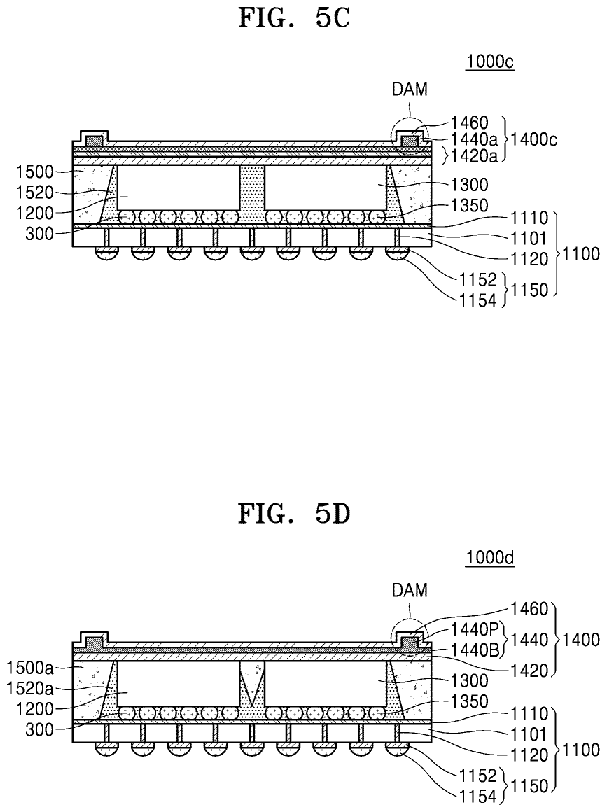

In the semiconductor package 1000 of the present embodiment, a case where the number of layers of the intermediate heat dissipation plate 1400 is three is illustrated, but the number of layers of the intermediate heat dissipation plate 1400 is not limited to three. In addition, the intermediate metal layer 1440 may not include the base 1440B, or the upper metal layer 1460 may be omitted. Various structures of the intermediate heat dissipation plate are described in more detail in the description of FIGS. 5A to 5D.

The sealant 1500 may cover and seal the first semiconductor device 1200 and the second semiconductor device 1300 on the interposer 1100. As illustrated in FIG. 1, the sealant 1500 may not cover the upper surfaces of the first semiconductor device 1200 and the second semiconductor device 1300. For example, the upper surface of the sealant 1500 may be coplanar with the upper surfaces of the first semiconductor device 1200 and the second semiconductor device 1300. Such a structure may be derived from a back-grinding process for the sealant 1500. However, in some embodiments, the upper surface of at least one of the first semiconductor device 1200 and the second semiconductor device 1300, for example, the first semiconductor device 1200, may be covered by the sealant 1500.

The sealant 1500 may include an insulating material, for example, a thermosetting resin (e.g., epoxy resin), a thermoplastic resin (e.g., polyimide), or a resin including a reinforcing material (e.g., an inorganic filler). For example, the sealant 1500 may include Ajinomoto build-up film (ABF), FR-4, BT resin, or the like. In addition, the sealant 1500 may include a molding material (e.g., an epoxy mold compound (EMC)) or a photosensitive material (e.g., a photo imageable encapsulant (PIE)). However, the material of the sealant 1500 is not limited to the materials described above.

On the other hand, underfill 1520 may fill a gap between the first semiconductor device 1200 and the interposer 1100 and a gap between the second semiconductor device 1300 and the interposer 1100. In addition, the underfill 1520 may fill a gap between the first connection terminals 300 and a gap between the second connection terminals 1350. On the other hand, the underfill 1520 may protrude from side surfaces of each of the first semiconductor device 1200 and the second semiconductor device 1300, e.g., in horizontal directions, and may cover at least a portion of the side surfaces of each of the first semiconductor device 1200 and the second semiconductor device 1300. In addition, when the gap between the first semiconductor device 1200 and the second semiconductor device 1300 is narrow, the underfill 1520 may fill the gap between the first semiconductor device 1200 and the second semiconductor device 1300, as illustrated in FIG. 1.

In some embodiments, the underfill 1520 may be replaced with an adhesive layer or an adhesive film. The adhesive layer or the adhesive film may include, for example, a non-conductive film (NCF). The NCF may be used as an adhesive layer, for example, when semiconductor chips are bonded by using thermal compression bonding (TCB) in a semiconductor chip stacking process. However, the material of the adhesive layer or the adhesive film is not limited to the NCF.

The semiconductor package 1000 of the present embodiment may have a chip-type package structure in which the first semiconductor device 1200 and the second semiconductor device 1300 are sealed with the sealant 1500 on the interposer 1100. The chip-type package may be a MIP chip or a chip package. The semiconductor package 1000 of the present embodiment may have a chip package structure including the intermediate heat dissipation plate 1400 on an upper side/part thereof. In addition, the dam DAM may be formed on an outer portion of the upper surface of the intermediate heat dissipation plate 1400. For example, the dam DAM may be formed in an upper portion of the intermediate heat dissipation plate 1400 and along an edge portion of the intermediate heat dissipation plate 1400. Accordingly, in the structure in which the semiconductor package 1000 of the present embodiment is coupled to the heat dissipation structure 1700 through the TIM 1800, the pumping out of the TIM 1800 may be prevented by the dam DAM, and thus, the adhesive strength between the semiconductor package 1000 and the heat dissipation structure 1700 may be increased and the heat dissipation capability through the TIM 1800 may be improved. Furthermore, due to the increase in the adhesive strength between the heat dissipation structure 1700 and the semiconductor package 1000, the warpage of the semiconductor package 1000 may be improved and defects such as non-wet/short of the first external connection terminal 1150 may be improved.

FIGS. 4A to 4C are cross-sectional views illustrating the structure of the first semiconductor device 1200 in the semiconductor package 1000 of FIG. 1. The following description is given with reference to FIGS. 4A to 4C together with FIG. 1, and contents provided above in the description of FIGS. 1 to 3C may be briefly described or omitted.

Referring to FIG. 4A, in the semiconductor package 1000 of the present embodiment, the first semiconductor device 1200 may have an HBM package structure. For example, the first semiconductor device 1200 may include a base chip 100, memory chips 200, a first connection terminal 300, and an inner sealant 400.

The base chip 100 may include a chip body 101, an active layer 110, a through electrode 120, a connection pad 130, and a protection layer 140. As illustrated in FIG. 4A, the size of the base chip 100 may be greater than the size of the memory chips 200 arranged thereon. However, the size of the base chip 100 is not limited thereto. For example, in some embodiments, the size of the base chip 100 may be the same or substantially the same as the size of the memory chips 200.

The chip body 101 may include, for example, a semiconductor element, such as silicon (Si) or germanium (Ge). In certain embodiments, the chip body 101 may include a compound semiconductor, such as silicon carbide (SiC), gallium arsenide (GaAs), indium arsenide (InAs), or indium phosphide (InP). The chip body 101 may have a silicon-on-insulator (SOI) structure. For example, the chip body 101 may include a buried oxide (BOX) layer. The chip body 101 may include a structure such as a conductive region, for example, a well doped with impurities or a source/drain region doped with impurities. The chip body 101 may have various device isolation structures, such as a shallow trench isolation (STI) structure. A buried structure, layer, or pattern may be a structure, a pattern or a layer that is covered, at least partially, by another layer or pattern. For example, a top surface of the buried layer or pattern may be covered by the covering layer or the covering pattern. For example, the top surface of the buried layer or pattern may be at a lower level than a top surface of the covering layer or the covering pattern.

The active layer 110 may include an integrated circuit layer and a wiring layer on the integrated circuit layer. The integrated circuit layer may include various types of devices. For example, the integrated circuit layer may include various active and/or passive devices, such as transistors, logic devices, memory devices, system large scale integration (LSI), complementary metal-oxide semiconductor (CMOS) imaging sensors (CISs), or micro-electro-mechanical system (MEMS). The transistor may include, for example, a bipolar junction transistor (BJT) or a field effect transistor (FET), such as a planar FET or a FinFET. The memory devices and the logic devices are the same as the ones described for the first semiconductor device 1200 and/or the second semiconductor device 1300 of the semiconductor package 1000 of FIG. 1.

The wiring layer may electrically connect at least two devices to each other, may electrically connect the devices to the conductive region of the chip body 101, or may electrically connect the devices to the first connection terminal 300. In addition, the wiring layer may electrically connect the through electrode 120 and the first connection terminal 300 to each other. The wiring layer may include, for example, wirings and contacts, and/or vias. In the first semiconductor device 1200 of the present embodiment, the active layer 110 may be arranged below the chip body 101 and the through electrode 120. However, in some embodiments, the active layer 110 may be arranged above the chip body 101 and the through electrode 120.

In the first semiconductor device 1200 of the present embodiment, the base chip 100 may include a plurality of logic devices in the integrated circuit layer of the active layer 110. The base chip 100 may be arranged below the memory chips 200 and configured to integrate signals of the memory chips 200, transmit the integrated signals to the outside, and transmit external signals and power to the memory chips 200. For example, the base chip 100 may be a buffer chip or an interface chip.

In some embodiments, the base chip 100 may include a controller configured to control signal transmission between the memory chips 200 and an external device. When the base chip 100 includes the controller, the base chip 100 may be a logic chip or a control chip. In addition, in some embodiments, the base chip 100 may include a power management integrated circuit (PMIC) configured to manage power or clocks. For reference, when the base chip 100 is the buffer chip or the like, the memory chips 200 may be core chips.

In the first semiconductor device 1200 of the present embodiment, the base chip 100 is not limited to the buffer chip or the logic chip. For example, the base chip 100 may include a plurality of memory devices in the integrated circuit layer of the active layer 110. Accordingly, the base chip 100 may include a memory chip in certain embodiments.

The through electrode 120 may pass through the chip body 101 and extend lengthwise from the upper surface to the lower surface of the chip body 101 in a vertical direction. In some embodiments, the through electrode 120 may extend into the inside of the active layer 110. In the first semiconductor device 1200 of the present embodiment, the chip body 101 may include Si, and thus, the through electrode 120 may be a TSV.

The through electrode 120 may have a pillar shape and may include a barrier layer on the outer surface thereof and a buried conductive layer therein. The barrier layer may include at least one material selected from Ti, TIN, Ta, TaN, Ru, Co, Mn, WN, Ni, and NiB. The buried conductive layer may include at least one material selected from Cu, a Cu alloy, such as CuSn, CuMg, CuNi, CuZn, CuPd, CuAu, CuRe, or CuW, W, a W alloy, Ni, Ru, and Co. In some embodiments, an insulating layer may be arranged between the through electrode 120 and the chip body 101 and/or between the through electrode 120 and the active layer 110. The insulating layer may include, for example, an oxide layer, a nitride layer, a carbide layer, a polymer, or any combination thereof.

The connection pad 130 may be arranged on the upper surface of the chip body 101 and may be electrically connected to and/or contact the through electrode 120. The connection pad 130 may include, for example, at least one of aluminum (Al), copper (Cu), nickel (Ni), tungsten (W), platinum (Pt), or gold (Au). In the first semiconductor device 1200 of the present embodiment, the connection pad 130 of the base chip 100 may include Cu. However, the material of the connection pad 130 is not limited to Cu.

The protection layer 140 may be arranged on the upper surface of the chip body 101. The protection layer 140 may include, for example, an oxide layer, a nitride layer, a carbide layer, a polymer, or any combination thereof. In the first semiconductor device 1200 of the present embodiment, the protection layer 140 may have a single-layer or multilayer structure.

The connection pad 130 may be arranged in a structure that passes through at least a portion of the protection layer 140. For example, the connection pad 130 may have a structure that completely passes through the protection layer 140, e.g., in a vertical direction, or passes through a portion of an upper side/part of the protection layer 140 and may be arranged in a structure that is buried in the protection layer 140. The connection pad 130 may be electrically connected to and/or contact the through electrode 120 on the upper surface of the chip body 101 or inside the protection layer 140. In certain embodiments, although not illustrated, a protection layer may also be arranged on the lower surface of the active layer 110.

The memory chips 200 may be stacked on the base chip 100. In the first semiconductor device 1200 of the present embodiment, eight memory chips 200, for example, first to eighth memory chips 200-1 to 200-8, may be stacked on the base chip 100. However, the number of memory chips 200 stacked on the base chip 100 is not limited to eight. For example, two to seven memory chips 200 or nine or more memory chips 200 may be stacked on the base chip 100.

For reference, in the first semiconductor device 1200, the number of memory chips 200 may be 4n (where n is a natural number). Accordingly, the first semiconductor device 1200 may include the memory chips 200 in multiples of 4, such as 4, 8, or 12. In addition, four memory chips 200 may have the same stack ID and may be tested and operated together. For example, when the first semiconductor device 1200 includes eight memory chips 200, the first to fourth memory chips 200-1 to 200-4 may have a first stack ID, and the fifth to eighth memory chips 200-5 to 200-8 may have a second stack ID. However, the first semiconductor device 1200 is not limited to the number of memory chips 200 of multiples of 4 and the stack IDs described above. For example, the first semiconductor device 1200 may include the memory chips 200 in multiples of 2 and stack IDs corresponding thereto (e.g., each pair of the memory chips 200 having the same stack IDs), or may include the memory chips 200 in multiples of 8 and stack IDs corresponding thereto (e.g., each set of eight memory chips 200 having the same stack IDs).

The first to eighth memory chips 200-1 to 200-8 may have the same or substantially the same horizontal size (e.g., the same size in a plan view) and internal structure. However, the eighth memory chip 200-8 arranged at the top may not include a through electrode. In addition, as illustrated in FIG. 4A, the eighth memory chip 200-8 may be thicker than the other memory chips 200. In some embodiments, the overall height of the first semiconductor device 1200 may be controlled by adjusting the thickness of the eighth memory chip 200-8. Hereinafter, for convenience, a specific structure of the memory chip 200 is described with reference to the first memory chip 200-1.

The first memory chip 200-1 may include a chip body 201, an active layer 210, a through electrode 220, connection pads 230, and protection layers 240. The chip body 201 may be the same as the chip body 101 of the base chip 100, e.g., except for the size and thickness of the chip body 201.

The active layer 210 may include a plurality of memory devices. For example, the active layer 210 may include a volatile memory device, such as DRAM or SRAM, or a non-volatile memory device, such as PRAM, MRAM, FeRAM, or RRAM. For example, in the first semiconductor device 1200, the first memory chip 200-1 may include DRAMs in the active layer 210. Accordingly, the first memory chip 200-1 may be a DRAM chip. In addition, because the first semiconductor device 1200 is an HMB package, the first memory chip 200-1 may be a DRAM chip for HBM.

The through electrode 220 may pass through the chip body 201, or may pass through the chip body 201 and extend to the inside of the active layer 210. For example, in a case where the first memory chip 200-1 is divided into a cell area and a pad area and the through electrode 220 is formed only in the pad area, the through electrode 220 may pass through the chip body 201 and extend to the inside of the active layer 210. Other details regarding the through electrode 220 may be the same as those for the through electrode 120 of the base chip 100 unless the context indicates otherwise.

The connection pads 230 may include a lower connection pad 230d arranged on the lower surface of the active layer 210 and an upper connection pad 230u arranged on the upper surface of the chip body 101. In a general semiconductor chip, a chip pad may be arranged on a lower surface of an active layer. Accordingly, the lower connection pad 230d may correspond to the chip pad of the first memory chip 200-1.

The lower connection pad 230d may be electrically connected to and/or contact the wirings of the wiring layer of the active layer 210 on the lower surface of the active layer 210. In addition, the lower connection pad 230d may be electrically connected to the through electrode 220 through the wirings of the wiring layer. The upper connection pad 230u may be electrically connected to and/or contact the through electrode 220 on the upper surface of the chip body 201. The materials of the lower connection pad 230d and the upper connection pad 230u may be the same as those described for the connection pad 130 of the base chip 100.

The protection layers 240 may include a lower protection layer 240d arranged on the lower surface of the active layer 210 and an upper protection layer 240u arranged on the upper surface of the chip body 201. Each protection layer 240 may include, for example, an oxide layer, a nitride layer, a carbide layer, a polymer, or any combination thereof. The upper protection layer 240u may be the same as the protection layer 140 of the base chip 100 described above unless the context indicates otherwise.

The upper connection pad 230u may be arranged in a structure that passes through at least a portion of the upper protection layer 240u, e.g., in a vertical direction. For example, the upper connection pad 230u may have a structure that completely passes through the upper protection layer 240u, e.g., in the vertical direction, or passes through a portion of an upper side/part of the upper protection layer 240u, and may be arranged in a structure that is buried in the upper protection layer 240u. The upper connection pad 230u may be electrically connected to and/or contact the through electrode 220.

The lower connection pad 230d may be arranged in a structure that passes through at least a portion of the lower protection layer 240d, e.g., in a vertical direction. For example, a thick pad metal layer may be arranged inside the lower protection layer 240d, and the lower connection pad 230d may pass through a portion of the lower protection layer 240d and be electrically connected to and/or contact the pad metal layer. On the other hand, the pad metal layer may be electrically connected to and/or contact the wirings of the wiring layer of the active layer 210. The pad metal layer may include, for example, aluminum (Al). Accordingly, the lower connection pad 230d may be electrically connected to the wirings of the wiring layer through the pad metal layer and may also be electrically connected to the through electrode 220 through the wirings of the wiring layer.

In the first semiconductor device 1200 of the present embodiment, the memory chips 200 may be stacked on the base chip 100 or the memory chip 200 therebelow through inter-chip connection terminals 260. For example, each inter-chip connection terminal 260 may be arranged between the connection pad 130 of the base chip 100 and the lower connection pad 230d of the first memory chip 200-1. In addition, the inter-chip connection terminal 260 may be arranged between the upper connection pad 230u of a lower memory chip 200 and the lower connection pad 230d of an upper memory chip 200 in two adjacent memory chips 200. The inter-chip connection terminal 260 may be the same as the one described above for the first external connection terminal 1150 of the interposer 1100. For example, the inter-chip connection terminal 260 may include a solder, or may include a pillar and a solder.

In the first semiconductor device 1200 of the present embodiment, as the memory chips 200 are stacked through the inter-chip connection terminals 260, an adhesive layer 510 may be arranged between the base chip 100 and the first memory chip 200-1 and between two adjacent memory chips 200. For example, the adhesive layer 510 may fill a gap between the base chip 100 and the first memory chip 200-1 and between two adjacent memory chips 200 and cover side surfaces of the inter-chip connection terminals 260. In addition, the adhesive layer 510 may protrude from side surfaces of the memory chips 200, e.g., in horizontal directions, and cover the side surfaces of the memory chips 200, as illustrated in FIG. 4A. On the other hand, in some embodiments, the adhesive layer 510 may protrude from the side surfaces of the memory chips 200, e.g., in horizontal directions, and cover only a portion of the side surface of each of the memory chips 200. In this case, the adhesive layer 510 on an upper side/surface and the adhesive layer 510 on a lower side/surface of each of the memory chips 200 may not be attached to each other and may be separated from each other, e.g., on a side surface of each of the memory chips 200. For example, the inner sealant 400 may contact the side surfaces of the memory chips 200 in certain embodiments. The adhesive layer 510 may include, for example, an NCF. However, the material of the adhesive layer is not limited to the NCF.

The first connection terminal 300 may be arranged on the lower surface of the base chip 100. The first connection terminal 300 may be electrically connected to and/or contact the wirings of the wiring layer of the active layer 110. In addition, the first connection terminal 300 may be electrically connected to the through electrode 120 through the wirings of the wiring layer. On the other hand, although not illustrated, a chip pad may be arranged on the lower surface of the base chip 100, and the first connection terminal 300 may be arranged on and/or contact the chip pad.

The first connection terminal 300 may have a structure the same as or similar to the inter-chip connection terminals 260. For example, the first connection terminal 300 may include a solder. In some embodiments, the first connection terminal 300 may include a pillar and a solder. The pillar and the solder of the first connection terminal 300 may be the same as the ones described for the first external connection terminal 1150 of the interposer 1100 in the semiconductor package 1000 of FIG. 1.

The inner sealant 400 may surround the side surfaces of the memory chips 200 on the base chip 100. As illustrated in FIG. 4A, the inner sealant 400 may not cover the upper surface of the uppermost memory chip, for example, the eighth memory chip 200-8. Accordingly, the upper surface of the eighth memory chip 200-8 may be exposed from the inner sealant 400. However, in some embodiments, the inner sealant 400 may cover the upper surface of the uppermost memory chip, for example, the eighth memory chip 200-8. The inner sealant 400 may include, for example, an EMC. However, the material of the inner sealant 400 is not limited to the EMC.

Referring to FIG. 4B, in a semiconductor package 1000 of the present embodiment, a first semiconductor device 1200a may have an HBM package structure, but may differ from the first semiconductor device 1200 of FIG. 4A in that the first semiconductor device 1200a further includes a top dummy chip 500. For example, the first semiconductor device 1200a may include a base chip 100, memory chips 200, a first connection terminal 300, an inner sealant 400, and the top dummy chip 500. The base chip 100, the memory chips 200, the first connection terminal 300, and the inner sealant 400 may be the same as the ones described for the first semiconductor device 1200 of FIG. 4A. However, as the top dummy chip 500 is added, the inner sealant 400 may have a structure that covers up to side surfaces of the top dummy chip 500.

In the first semiconductor device 1200a, the top dummy chip 500 may be stacked on the memory chips 200 through an adhesive layer 520. The top dummy chip 500 may be added so as to satisfy the height specification of the first semiconductor device 1200a. For example, in the case of the HBM package, the height, area, and the like may be determined by the Joint Electron Device Engineering Council (JEDEC) standard. When the first semiconductor device 1200a is the HBM package, the height of the first semiconductor device 1200a may satisfy the JEDEC standard by arranging the top dummy chip 500 having an appropriate height on the memory chips 200.

On the other hand, as the top dummy chip 500 is added to the first semiconductor device 1200a, the eighth memory chip 200-8 may have a thickness the same as or similar to a thickness of each of the other memory chips 200. However, the inventive concept is not limited thereto. In some embodiments, even when the top dummy chip 500 is included, the eighth memory chip 200-8 may have a thickness greater than a thickness of each of the other memory chips 200. However, when the total height of the first semiconductor device 1200a is controlled by adjusting the thickness of the eighth memory chip 200-8, the top dummy chip 500 may be omitted.

Referring to FIG. 4C, in the semiconductor package 1000 of the present embodiment, a first semiconductor device 1200b may have an HBM package structure, but may differ from the first semiconductor device 1200 of FIG. 4A in that memory chips 200a are stacked through hybrid copper bonding (HCB). For example, the first semiconductor device 1200b may include a base chip 100, memory chips 200a, a first connection terminal 300, and an inner sealant 400. The base chip 100, the first connection terminal 300, and the inner sealant 400 may be the same as the ones described for the first semiconductor device 1200 of FIG. 4A. However, because the memory chips 200a are stacked through HCB without the inter-chip connection terminals 260, an adhesive layer filling a gap between the memory chip 200a and the base chip 100 and between the adjacent memory chips 200a may not exist.

In the first semiconductor device 1200b, the memory chips 200a may be stacked on the base chip 100 or the memory chip 200a directly therebelow through HCB. In addition, the memory chips 200a may be stacked on the base chip 100 or the memory chip 200a directly therebelow through HCB. The HCB may be a combination of pad-to-pad bonding and insulator-to-insulator bonding. On the other hand, because pads are usually formed of Cu, pad-to-pad bonding may be Cu-to-Cu bonding.

In more detail, as described above, a connection pad 130 and a protection layer 140 may be arranged on the upper surface of the base chip 100. In addition, a connection pad 230 and a protection layer 240 may be arranged on each of the lower surface and the upper surface of each of the memory chips 200a. On the other hand, the connection pad 130 of the base chip 100 may be arranged in a buried structure in the protection layer 140, and the upper surface of the connection pad 130 may be exposed from the protection layer 140. In addition, the connection pad 230 of the memory chip 200a may be arranged in a buried structure in the protection layer 240, and the upper surface or the lower surface of the connection pad 230 may be exposed from the protection layer 240. Each of the protection layers 140 and 240 may include, for example, an insulating layer, such as SiO2 or SiN.

The connection pad 130 of the base chip 100 may be electrically coupled to and contact a lower connection pad 230d of a first memory chip 200a-1, and the protection layer 140 of the base chip 100 may be coupled to a lower protection layer 240d of the first memory chip 200a-1 so that HCB may be formed between the base chip 100 and the first memory chip 200a-1. In addition, HCB may be formed between two adjacent memory chips 200a by coupling an upper connection pad 230u and an upper protection layer 240u on the upper surface of a lower memory chip 200a to the lower connection pad 230d and the lower protection layer 240d on the lower surface of an upper memory chip 200a.

FIGS. 5A to 5D are cross-sectional views of semiconductor packages according to embodiments. The following description is given with reference to FIGS. 5A to 5D together with FIG. 1, and contents provided above in the description of FIGS. 1 to 4C may be briefly described or omitted.

Referring to FIG. 5A, a semiconductor package 1000a of the present embodiment may differ from the semiconductor package 1000 of FIG. 1 in a structure of an intermediate heat dissipation plate 1400a. For example, the semiconductor package 1000a of the present embodiment may include an interposer 1100, a first semiconductor device 1200, a second semiconductor device 1300, an intermediate heat dissipation plate 1400a, and a sealant 1500. The interposer 1100, the first semiconductor device 1200, the second semiconductor device 1300, and the sealant 1500 may be the same as the ones described for the semiconductor package 1000 of FIG. 1.

In the semiconductor package 1000a of the present embodiment, the intermediate heat dissipation plate 1400a may have a single layer structure. For example, the intermediate heat dissipation plate 1400a may have the same or substantially the same structure as the intermediate metal layer 1440 of the intermediate heat dissipation plate 1400 in the semiconductor package 1000 of FIG. 1. Accordingly, the intermediate heat dissipation plate 1400a may include a base 1400B and a protrusion 1400P on the outer portion of the upper surface of the base 1400B. The base 1400B and the protrusion 1400P may be the same as the ones described for the intermediate metal layer 1440 of the intermediate heat dissipation plate 1400. However, the base 1400B may be thicker than the base 1440B of the intermediate metal layer 1440.

On the other hand, because the intermediate heat dissipation plate 1400a does not include a lower metal layer and an upper metal layer, the protrusion 1400P of the intermediate heat dissipation plate 1400a may form a dam DAM on its own. The protrusion 1400P may have various shapes, as illustrated in FIGS. 2A to 2C. In addition, the shape of the dam DAM may also be determined according to the shape of the protrusion 1400P.

Referring to FIG. 5B, a semiconductor package 1000b of the present embodiment may differ from the semiconductor package 1000 of FIG. 1 in a structure of an intermediate heat dissipation plate 1400b. For example, the semiconductor package 1000b of the present embodiment may include an interposer 1100, a first semiconductor device 1200, a second semiconductor device 1300, an intermediate heat dissipation plate 1400b, and a sealant 1500. The interposer 1100, the first semiconductor device 1200, the second semiconductor device 1300, and the sealant 1500 may be the same as the ones described for the semiconductor package 1000 of FIG. 1.

In the semiconductor package 1000b of the present embodiment, the intermediate heat dissipation plate 1400b may include a lower metal layer 1420, an intermediate metal layer 1440a, and an upper metal layer 1460. The lower metal layer 1420 may be the same as the lower metal layer 1420 of the intermediate heat dissipation plate 1400 in the semiconductor package 1000 of FIG. 1. The intermediate metal layer 1440a may have a structure that includes only the protrusion. For example, the intermediate metal layer 1440a may correspond to or may be a structure in which the base 1440B is not present in the intermediate metal layer 1440 of the intermediate heat dissipation plate 1400 in the semiconductor package 1000 of FIG. 1. The upper metal layer 1460 may be the same as the upper metal layer 1460 of the intermediate heat dissipation plate 1400 in the semiconductor package 1000 of FIG. 1. However, because the intermediate metal layer 1440a has a structure that includes only the protrusion, the upper metal layer 1460 may cover the upper surfaces of the intermediate metal layer 1440a and the lower metal layer 1420 with a uniform thickness. On the other hand, the dam DAM may include the intermediate metal layer 1440a and a protruding portion of the upper metal layer 1460 covering the intermediate metal layer 1440a. In addition, the intermediate metal layer 1440a may have various shapes, as illustrated in FIGS. 2A to 2C, and the shape of the dam DAM may also be determined according to the shape of the intermediate metal layer 1440a.

Referring to FIG. 5C, a semiconductor package 1000c of the present embodiment may differ from the semiconductor package 1000 of FIG. 1 in a structure of an intermediate heat dissipation plate 1400c. For example, the semiconductor package 1000c of the present embodiment may include an interposer 1100, a first semiconductor device 1200, a second semiconductor device 1300, an intermediate heat dissipation plate 1400c, and a sealant 1500. The interposer 1100, the first semiconductor device 1200, the second semiconductor device 1300, and the sealant 1500 may be the same as the ones described for the semiconductor package 1000 of FIG. 1.

In the semiconductor package 1000c of the present embodiment, the intermediate heat dissipation plate 1400c may include a lower metal layer 1420a, an intermediate metal layer 1440a, and an upper metal layer 1460. The intermediate metal layer 1440a and the upper metal layer 1460 may be respectively the same as the intermediate metal layer 1440a and the upper metal layer 1460 of the intermediate heat dissipation plate 1400b in the semiconductor package 1000b of FIG. 5B.

The lower metal layer 1420a may have a multilayer structure. For example, the lower metal layer 1420a in the semiconductor package 1000c of the present embodiment may have a three-layer structure. However, the number of layers of the lower metal layer 1420a is not limited to three. For example, the lower metal layer 1420a may have a structure of two, or four or more layers. Each of the three layers of the lower metal layer 1420a may have a flat plate shape. In addition, each of the three layers of the lower metal layer 1420a may include one of the metal materials described above. On the other hand, the three layers of the lower metal layer 1420a may be distinguished from each other because the three layers of the lower metal layer 1420a include different metal materials or are formed in different process conditions even when including the same material.

Referring to FIG. 5D, a semiconductor package 1000d of the present embodiment may differ from the semiconductor package 1000 of FIG. 1 in a structure of a sealant 1500a. Specifically, the semiconductor package 1000d of the present embodiment may include an interposer 1100, a first semiconductor device 1200, a second semiconductor device 1300, an intermediate heat dissipation plate 1400, and a sealant 1500a. The interposer 1100, the first semiconductor device 1200, the second semiconductor device 1300, and the intermediate heat dissipation plate 1400 may be the same as the ones described for the semiconductor package 1000 of FIG. 1.

In the semiconductor package 1000d of the present embodiment, the sealant 1500a may also be arranged between the first semiconductor device 1200 and the second semiconductor device 1300. Specifically, the first semiconductor device 1200 and the second semiconductor device 1300 may be arranged on the interposer 1100 at a certain interval. Accordingly, underfill 1520a may not completely fill a gap between the first semiconductor device 1200 and the second semiconductor device 1300 and may cover/contact only and at least a portion of side surfaces of the first semiconductor device 1200 and the second semiconductor device 1300. As a result, a space that is not filled by the underfill 1520a may exist between the first semiconductor device 1200 and the second semiconductor device 1300, and the space may be filled by the sealant 1500a. For example, the sealant 1500a may be formed between the first semiconductor device 1200 and the second semiconductor device 1300 such that the sealant 1500a disposed between the first semiconductor device 1200 and the second semiconductor device 1300 overlaps the first semiconductor device 1200 and the second semiconductor device 1300 in a horizontal direction.

In addition, in the semiconductor packages 1000 and 1000a to 1000d of FIGS. 1 and 5A to FIG. 5D, the underfills 1520 and 1520a are illustrated as completely covering the side surfaces of the first semiconductor device 1200 and the second semiconductor device 1300, but the structures of the underfills 1520 and 1520a are not limited thereto. For example, the underfills 1520 and 1520a may cover/contact only a lower portion of the side surfaces of the first semiconductor device 1200 and the second semiconductor device 1300.

FIGS. 6A and 6B are cross-sectional views of system packages according to embodiments. The following description is given with reference to FIGS. 6A and 6B together with FIG. 1, and contents provided above in the description of FIGS. 1 to 5D may be briefly described or omitted.

Referring to FIG. 6A, a system package 2000 of the present embodiment may include a semiconductor package 1000, a package substrate 1600, and a heat dissipation structure 1700. The semiconductor package 1000 may be, for example, the semiconductor package 1000 of FIG. 1. Accordingly, the semiconductor package 1000 may include the interposer 1100, the first semiconductor device 1200, the second semiconductor device 1300, the intermediate heat dissipation plate 1400, and the sealant 1500. On the other hand, the semiconductor package 1000 in the system package 2000 of the present embodiment is not limited to the semiconductor package 1000 of FIG. 1. For example, instead of the semiconductor package 1000 of FIG. 1, the semiconductor packages 1000a to 1000d of FIGS. 5A to 5D may be applied to the system package 2000. In addition, the first semiconductor device 1200 is not limited to the HBM package structure of the first semiconductor device 1200 of FIG. 4A, and may have the HBM package structures of the first semiconductor devices 1200a and 1200b of FIGS. 4B and 4C. Furthermore, the first semiconductor device 1200 may have a general package structure other than the HBM package, or may have a single memory chip structure.

In the system package 2000 of the present embodiment, the package substrate 1600 may serve as or may be a support substrate, and the semiconductor package 1000 and the heat dissipation structure 1700 may be stacked on the package substrate 1600. The semiconductor package 1000 may be mounted on the package substrate 1600 through first external connection terminals 1150 and an underfill 1160. The package substrate 1600 may include a substrate body 1601 and a substrate protection layer 1620. The substrate body 1601 may include one or more wiring layers therein. When the wiring is formed in multiple layers, conductive patterns of different wiring layers may be electrically connected to each other through vertical vias. The package substrate 1600 may include or may be, for example, a ceramic substrate, a printed circuit board (PCB), an organic substrate, an interposer substrate, or the like according to the material of the substrate body 1601.

The package substrate 1600 may include two substrate protection layers 1620 including an upper substrate protection layer 1620u on the upper surface of the substrate body 1601 and a lower substrate protection layer 1620d on the lower surface of the substrate body 1601. The substrate protection layer 1620 may include, for example, solder resist (SR). However, the material of the substrate protection layer 1620 is not limited to the SR. On the other hand, a second external connection terminal 1650 may be arranged on the lower surface of the package substrate 1600. The system package 2000 may be stacked on an external system board or main board through the second external connection terminal 1650.

The heat dissipation structure 1700 may include a top plate 1710 and a side plate 1730. The top plate 1710 may have a flat plate shape. The side plate 1730 may extend vertically downward from the outer end of the top plate 1710. A lower end of the side plate 1730 may be in contact with the upper surface of the package substrate 1600. The top plate 1710 and the side plate 1730 may be integrally connected to each other as one body. The heat dissipation structure 1700 may include a metal material that has high thermal conductivity and is relatively lightweight. For example, the heat dissipation structure 1700 may include an aluminum alloy. However, the material of the heat dissipation structure 1700 is not limited to the aluminum alloy. The heat dissipation structure 1700 may be, for example, a heat slug.

The heat dissipation structure 1700 may be adhesively fixed to the semiconductor package 1000 through a TIM 1800. Specifically, the top plate 1710 of the heat dissipation structure 1700 may be adhesively fixed to the intermediate heat dissipation plate 1400 through the TIM 1800. The TIM 1800 may include a gel type material with high thermal conductivity, e.g., a material with low thermal resistance, such as grease, tape, an elastomer-filled pad, or a phase transition material. The TIM 1800 may be, for example, a gel type. However, the TIM 1800 is not limited to the gel type. On the other hand, as described above, the TIM 1800 may be surrounded by the dam DAM of the intermediate heat dissipation plate 1400. Accordingly, in a TC reliability test, the TIM 1800 may be prevented from being pumped out to the outside and the TIM 1800 may be maintained on the intermediate heat dissipation plate 1400, and thus, the heat dissipation efficiency through the TIM 1800 may be improved. In addition, because the adhesive strength between the heat dissipation structure 1700 and the intermediate heat dissipation plate 1400 is strongly maintained through the TIM 1800, warpage of the semiconductor package 1000 may be reduced. As a result, defects, such as non-wet/short of the first external connection terminals 1150 of the semiconductor package 1000, may be minimized.

The structure of the system package 2000 of the present embodiment may be a 2.5D package structure. The 2.5D package structure may be a relative concept to a 3D package structure in which all semiconductor chips are stacked together and no interposer exists. Each of the 2.5D package structure and the 3D package structure may be included in or may be a system in package (SIP) structure. In addition, the system package 2000 of the present embodiment may be a semiconductor package, e.g., in a broad meaning, but the system package may be distinguished from the semiconductor package 1000 that is a component of the system package 2000 as described in the present disclosure. Similarly, the other system packages described below may also be semiconductor packages, e.g., in a broad meaning.

Referring to FIG. 6B, a system package 2000a of the present embodiment may differ from the system package 2000 of FIG. 6A in a structure of a heat dissipation structure 1700a. Specifically, the system package 2000a of the present embodiment may include a semiconductor package 1000, a package substrate 1600, and the heat dissipation structure 1700a. The semiconductor package 1000 and the package substrate 1600 may be the same as the ones described for the system package 2000 of FIG. 6A.

In the system package 2000a of the present embodiment, the heat dissipation structure 1700a may include a heat dissipation plate 1720 and a stiffener 1740. The heat dissipation plate 1720 may have a thick flat plate shape. For example, the heat dissipation plate 1720 may have a thickness of 15% to 25% of the smaller of the width/length of the heat dissipation plate 1720. The heat dissipation plate 1720 may include a metal material that has high thermal conductivity (e.g., greater than 170 or greater than 200 watts per meter-kelvin (W·m⁻¹·K⁻¹) and is relatively lightweight. For example, the heat dissipation plate 1720 may include an aluminum alloy. However, the material of the heat dissipation plate 1720 is not limited to the aluminum alloy. The heat dissipation plate 1720 may be, for example, a heat sink.

The stiffener 1740 may be arranged between the heat dissipation plate 1720 and the package substrate 1600 and may support the heat dissipation plate 1720. The stiffener 1740 may improve thermal characteristics of the package substrate 1600, for example, warpage characteristics of the package substrate 1600 by mechanically supporting the package substrate 1600 and the heat dissipation plate 1720 between the package substrate 1600 and the heat dissipation plate 1720. The stiffener 1740 may include metal, such as steel or Cu, which has excellent mechanical strength. However, the material of the stiffener 1740 is not limited thereto. The materials of the stiffener 1740 and the heat dissipation plate 1720 may be different from each other. Therefore, the stiffener 1740 and the heat dissipation plate 1720 may not be integrally coupled to each other. However, in some embodiments, the stiffener 1740 and the heat dissipation plate 1720 may include the same metal.

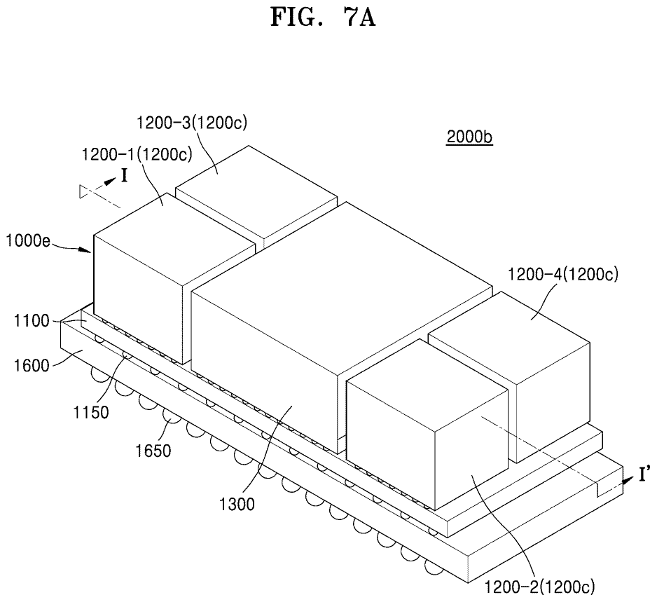

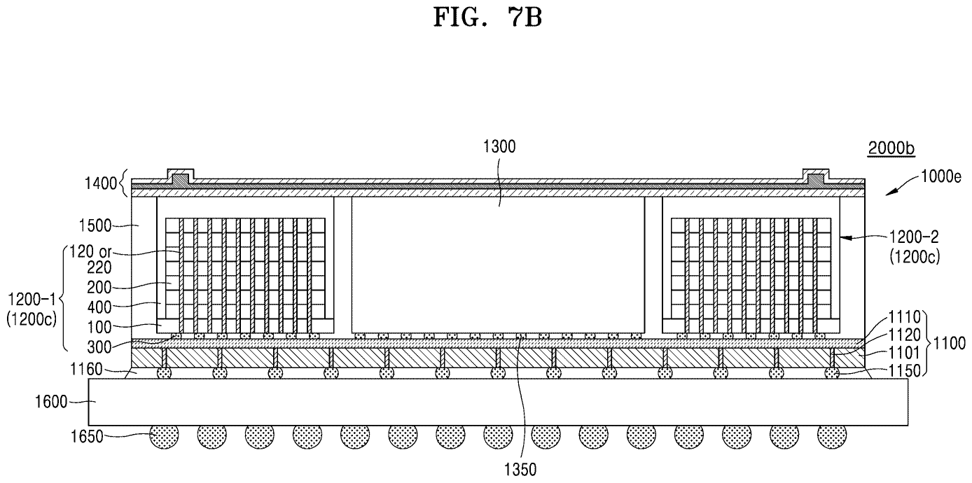

FIGS. 7A and 7B are respectively a perspective view and a cross-sectional view of a system package according to an embodiment. FIG. 7B may be a cross-sectional view taken along line I-I′ of FIG. 7A. The following description is given with reference to FIGS. 7A and 7B together with FIGS. 1 and 6A, and contents provided above in the description of FIGS. 1 to 6B may be briefly described or omitted. In FIG. 7A, for convenience, an intermediate heat dissipation plate 1400, a sealant 1500, a heat dissipation structure 1700, and a TIM 1800 are omitted. In FIG. 7B, for convenience, the heat dissipation structure 1700 and the TIM 1800 are omitted. Therefore, elements not shown in the drawings and/or not described in the below description should be referenced from the above descriptions and previous drawings (e.g., FIGS. 1 to 6B).

Referring to FIGS. 7A and 7B, a system package 2000b of the present embodiment may differ from the system package 2000 of FIG. 6A in that a semiconductor package 1000e includes four first semiconductor devices 1200c. Specifically, the system package 2000b of the present embodiment may include the semiconductor package 1000e, a package substrate 1600, and a heat dissipation structure 1700. The package substrate 1600 and the heat dissipation structure 1700 may be the same as the ones described for the system package 2000 of FIG. 6A.

In the system package 2000b of the present embodiment, the semiconductor package 1000e may include an interposer 1100, a first semiconductor device 1200c, a second semiconductor device 1300, an intermediate heat dissipation plate 1400, and a sealant 1500. The interposer 1100, the second semiconductor device 1300, the intermediate heat dissipation plate 1400, and the sealant 1500 may be the same as the ones described for the semiconductor package 1000 of FIG. 1.

In the system package 2000b of the present embodiment, the semiconductor package 1000e may include four first semiconductor devices 1200c, as illustrated in FIG. 7A. For example, four first semiconductor devices 1200c may be arranged on the interposer 1100 through first connection terminals 300, two on each of opposite sides of the second semiconductor device 1300. Specifically, a lower left first semiconductor device 1200-1 and an upper left first semiconductor device 1200-3 may be arranged on the left side of the second semiconductor device 1300, and a lower right first semiconductor device 1200-2 and an upper right first semiconductor device 1200-4 may be arranged on the right side of the second semiconductor device 1300. However, in a system package 2000b of the present embodiment, the number of first semiconductor devices 1200c is not limited to four. For example, one to three first semiconductor devices 1200c or five or more first semiconductor devices 1200c may be arranged on the interposer 1100.

The first semiconductor device 1200c may be, for example, the first semiconductor device 1200 of FIG. 4A. Accordingly, the first semiconductor device 1200c may include a base chip 100, memory chips 200, a first connection terminal 300, and an inner sealant 400. However, the first semiconductor device 1200c is not limited to the first semiconductor device 1200 of FIG. 4A. For example, the first semiconductor devices 1200a and 1200b of FIG. 4B or 4C may be applied to the first semiconductor device 1200c of the semiconductor package 1000e of the system package 2000b.

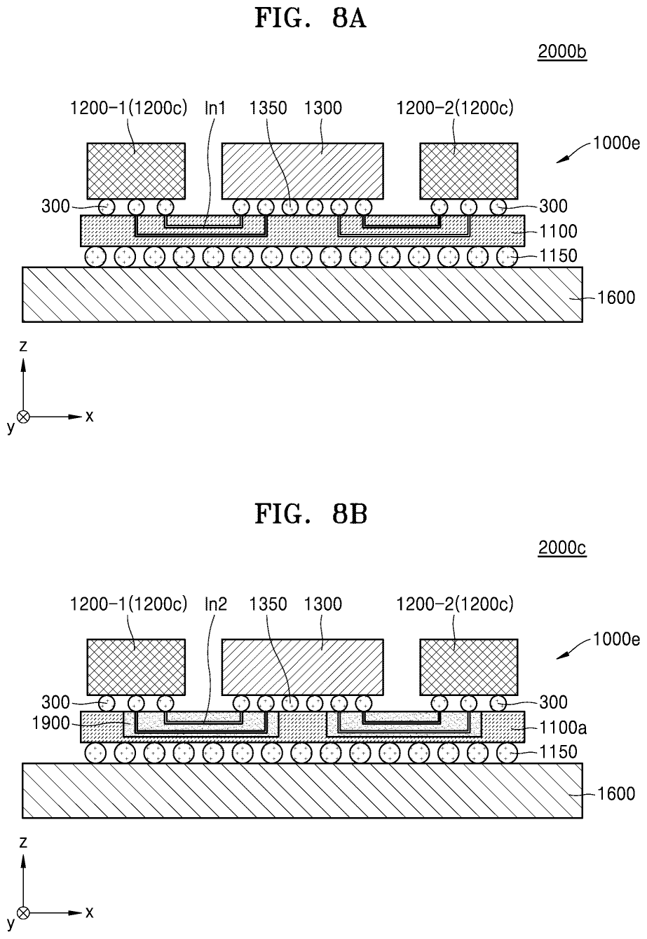

FIGS. 8A and 8B are cross-sectional views of system packages according to embodiments. Elements described above with reference to FIGS. 1 to 7B may be briefly described or omitted. For reference, FIGS. 8A and 8B are cross-sectional views corresponding to FIG. 7B, and from the viewpoint of the connection structure between the first semiconductor device 1200 and the second semiconductor device 1300, only the interposer 1100 (1100a), the first semiconductor device 1200, the second semiconductor device 1300, and the package substrate 1600 are schematically illustrated, and the second external connection terminal, the sealant, or the like are not illustrated.

Referring to FIG. 8A, a system package 2000b of the present embodiment may be the same or substantially the same as the system package 2000b of FIG. 7B. Accordingly, the system package 2000b of the present embodiment may include a semiconductor package 1000e, a package substrate 1600, and a heat dissipation structure (not shown). The package substrate 1600 and the heat dissipation structure 1700 are the same as the ones described for the system package 2000 of FIG. 6A. The semiconductor package 1000e is the same as the one described for the semiconductor package 1000e of the system package 2000b of FIG. 7B.

In the semiconductor package 1000e, a first semiconductor device 1200c may be mounted on an interposer 1100 through first connection terminals 300, and a second semiconductor device 1300 may be mounted on the interposer 1100 through second connection terminals 1350. As illustrated in FIG. 8A, in the system package 2000bof the present embodiment, the first semiconductor device 1200c and the second semiconductor device 1300 may be electrically connected through a first connection wiring In1 of the interposer 1100. On the other hand, the first connection wiring In1 may include a wiring of a wiring layer 1110 of the interposer 1100 and a through electrode 1120, or may include a wiring of the wiring layer 1110 of the interposer 1100 and not include a through electrode 1120.

Referring to FIG. 8B, a system package 2000c of the present embodiment may include a semiconductor package 1000e, a package substrate 1600, a heat dissipation structure (not shown), and Si-bridges 1900. The system package 2000 c of the present embodiment may further include the Si-bridges 1900, compared to the system package 2000b of FIG. 8A. In addition, the interposer 1100a may be based on an organic material, plastic, or a glass substrate rather than Si. However, the material of the interposer 1100a is not limited to the materials described above. In some embodiments, the interposer 1100a may be, for example, a panel interposer, a PLP interposer, or an RDL interposer (redistribution layer interposer or redistribution interposer).

The Si-bridge 1900 may be arranged inside the interposer 1100 a, as illustrated in FIG. 8B. The Si-bridge 1900 may be arranged inside the interposer 1100a at a corresponding position between the first semiconductor device 1200c and the second semiconductor device 1300. In addition, the Si-bridge 1900 may overlap a portion of the first semiconductor device 1200c and a portion of the second semiconductor device 1300, e.g., in a vertical direction. In the system package 2000c of the present embodiment, the first semiconductor device 1200c may be arranged on both sides of the second semiconductor device 1300 in the x direction. Accordingly, the Si-bridges 1900 may be arranged on both sides of the second semiconductor device 1300 in the x direction.

The Si-bridge 1900 may include a second connection wiring In2 therein. The Si-bridge 1900 may electrically connect the first semiconductor device 1200 c and the second semiconductor device 1300 to each other through the second connection wiring In2. As a result, in the system package 2000c of the present embodiment, the first semiconductor device 1200c and the second semiconductor device 1300 may be electrically connected to each other by using the Si-bridge 1900 separately arranged inside the interposer 1100a.

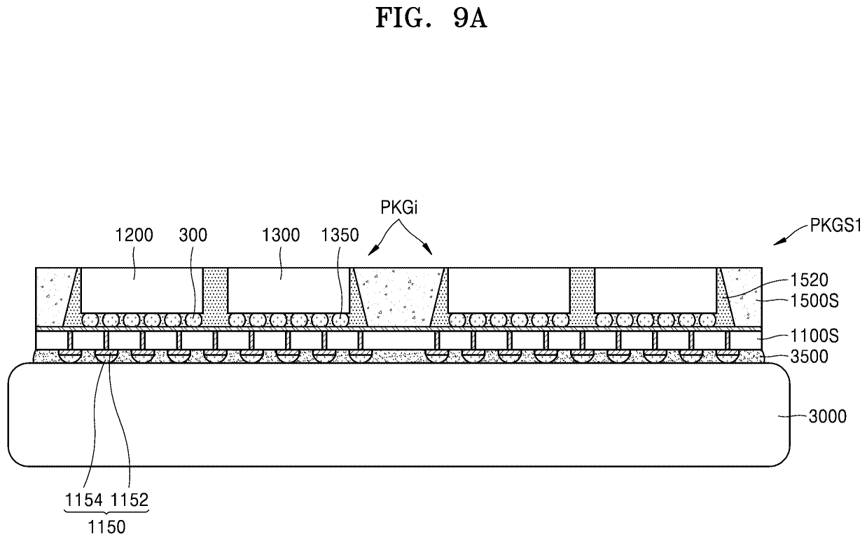

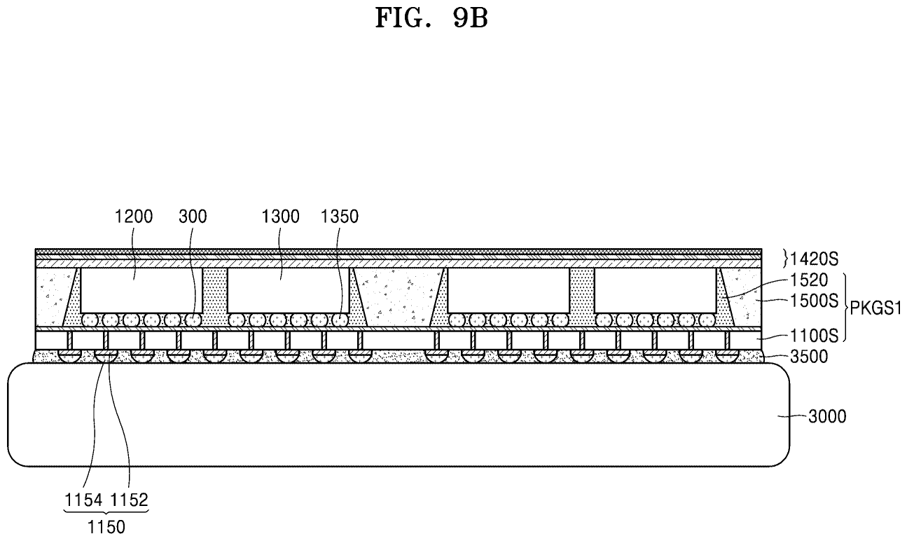

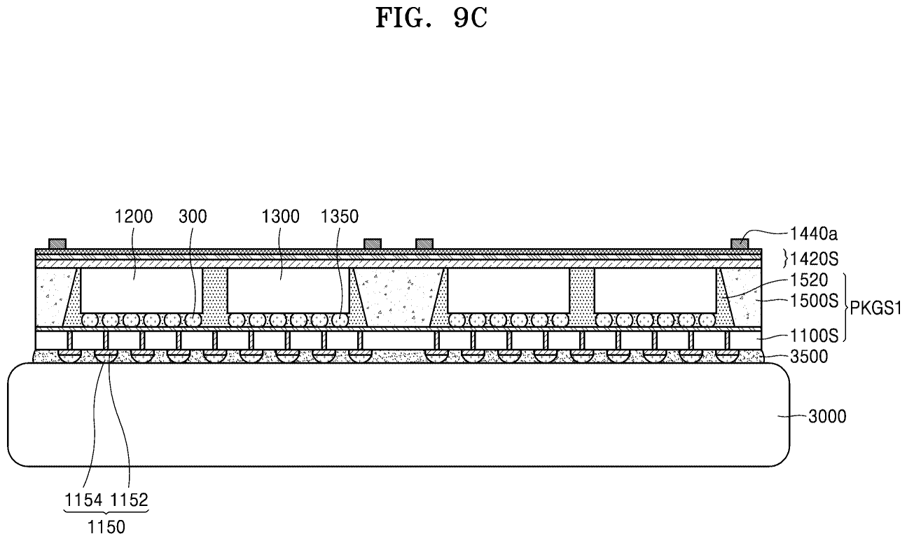

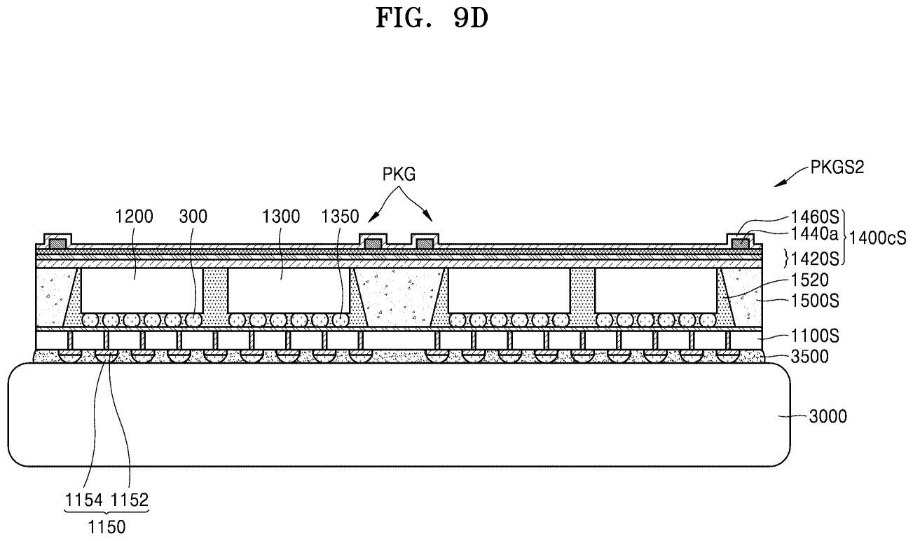

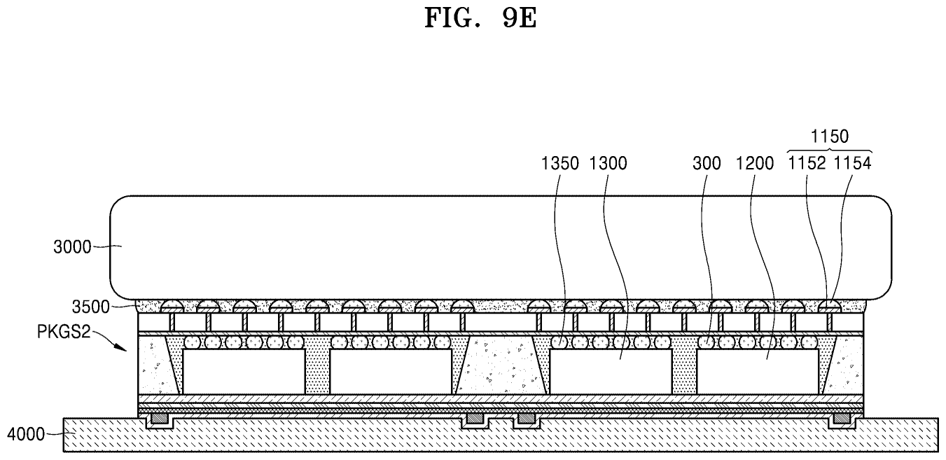

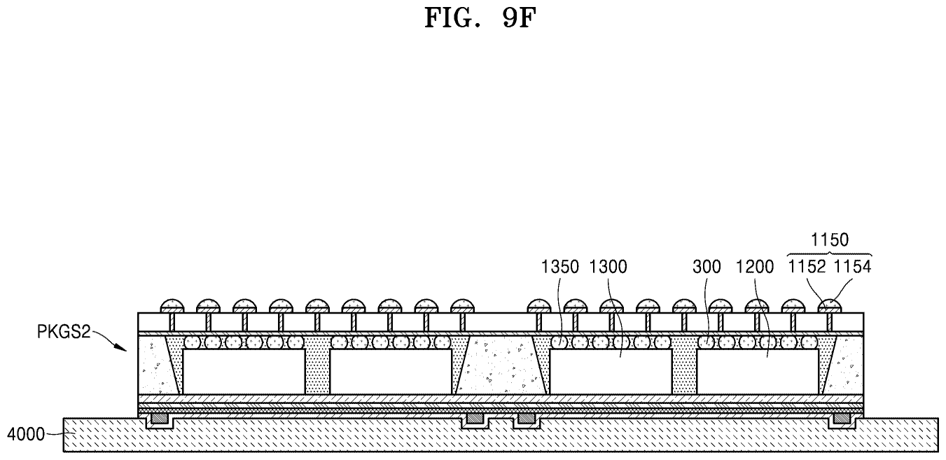

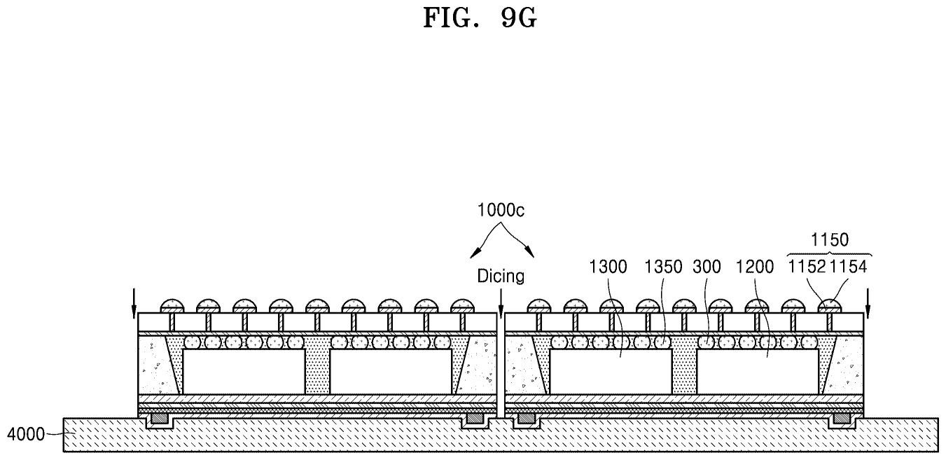

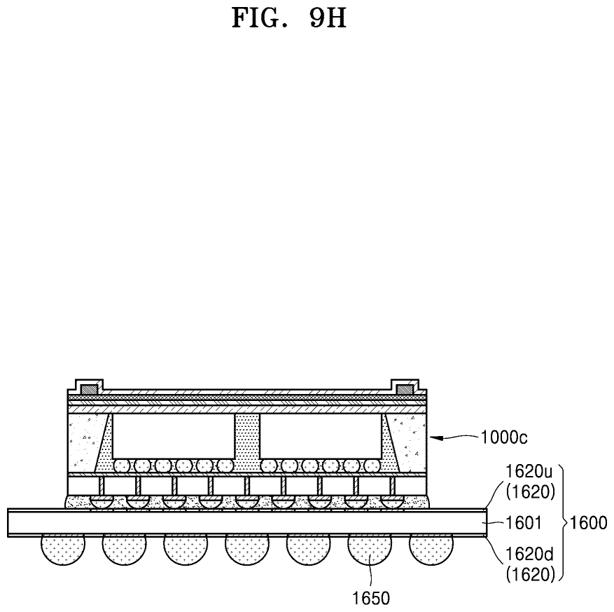

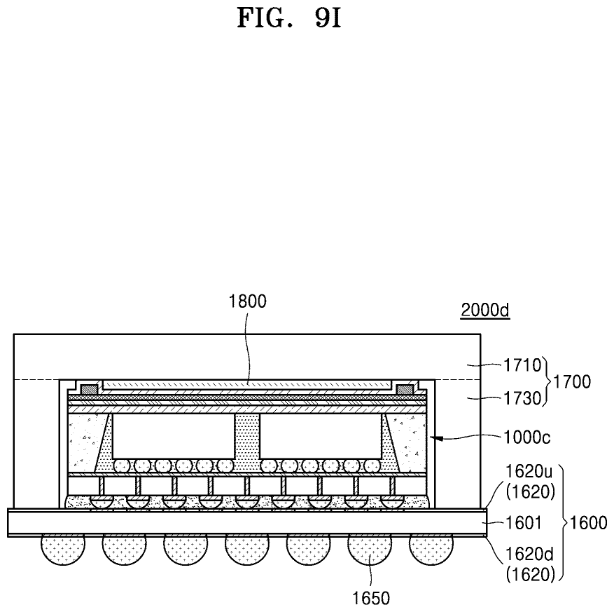

FIGS. 9A to 9I are cross-sectional views schematically illustrating a method of manufacturing a system package, according to an embodiment. The following description is given with reference to FIGS. 9A to 9I together with FIG. 1, and contents provided above in the description of FIGS. 1 to 8B may be briefly described or omitted.

Referring to FIG. 9A, the method of manufacturing a system package, according to the present embodiment, may include preparing a first package structure PKGS1 including a plurality of initial chip packages PKGi. The first package structure PKGS1 may be adhesively fixed on a carrier substrate 3000 through an adhesive layer 3500, as illustrated in FIG. 9A.

The first package structure PKGS1 may include an interposer structure 1100S, a plurality of first semiconductor devices 1200, a plurality of second semiconductor devices 1300, and a sealant structure 1500S. The interposer structure 1100S may include a plurality of interposers corresponding to the initial chip packages PKGi. For example, the interposer structure 1100S may have a wafer-level size (e.g., a wafer size) and include a plurality of interposers.

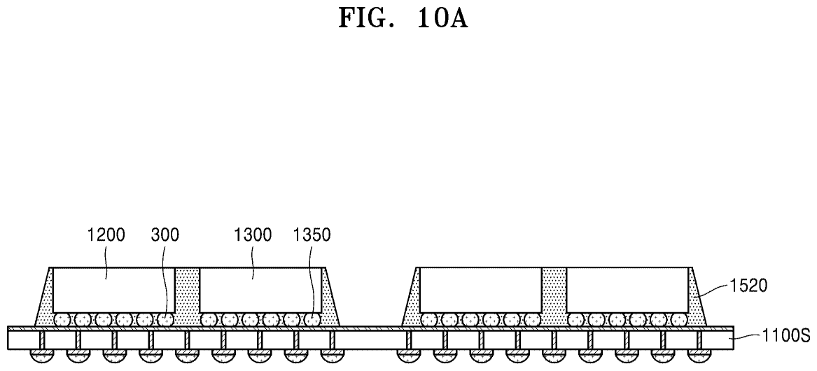

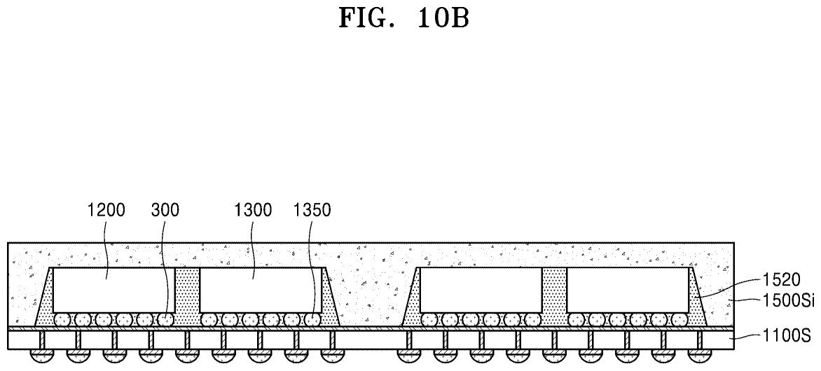

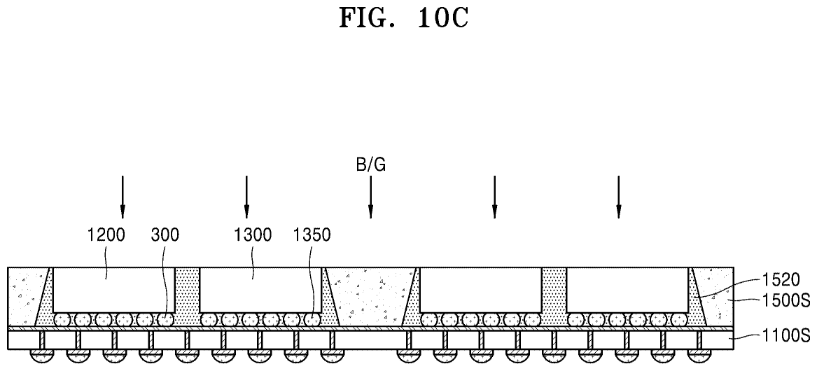

The sealant structure 1500S may seal all the first semiconductor devices 1200 and the second semiconductor devices 1300 on the interposer structure 1100S. For example, the sealant structure 1500S may seal the first semiconductor devices 1200 and the second semiconductor devices 1300 at a wafer level (e.g., on a wafer size substrate). On the other hand, as illustrated in FIG. 9A, underfill 1520 may cover/fill a gap between the first semiconductor devices 1200 and the interposer structure 1100S, and a gap between the second semiconductor devices 1300 and the interposer structure 1100S, and may cover/contact side surfaces of each of the first semiconductor devices 1200 and the second semiconductor devices 1300, and the sealant structure 1500S may cover/contact side surfaces of the underfill 1520. However, in some embodiments, a portion of the side surfaces of each of the first semiconductor devices 1200 and the second semiconductor devices 1300 may be exposed from the underfill 1520, and the sealant structure 1500S may cover/contact the side surfaces of the underfill 1520 and the exposed portion of the side surfaces of each of the first semiconductor devices 1200 and the second semiconductor devices 1300. On the other hand, the sealant structure 1500S may not cover the upper surface of each of the first semiconductor devices 1200 and the second semiconductor devices 1300. In addition, the upper surface of the sealant structure 1500S and the upper surfaces of each of the first semiconductor devices 1200 and the second semiconductor devices 1300 may be coplanar or substantially coplanar, e.g., formed on the same plane. This may be due to a back-grinding process (see B/G of FIG. 10C) for the sealant structure 1500S when manufacturing the first package structure PKGS1. The process of manufacturing the first package structure PKGS1 is described in more detail in the description of FIGS. 10A to 10C.

On the other hand, each of the first semiconductor devices 1200 may correspond to, e.g., the same as, the first semiconductor device 1200 of the semiconductor package 1000 of FIG. 1, and each of the second semiconductor devices 1300 may correspond to, e.g., the same as, the second semiconductor device 1300 of the semiconductor package 1000 of FIG. 1. Each of the first semiconductor devices 1200 may have an HBM package structure. Accordingly, each of the first semiconductor devices 1200 may have one of the HBM package structures of the first semiconductor devices 1200, 1200a, and 1200b of FIGS. 4A to 4C.

The first semiconductor devices 1200 and the second semiconductor devices 1300 may be paired or grouped and mounted on the corresponding portions of the interposer structure 1100S. For example, as illustrated in FIG. 9A, one first semiconductor device 1200 and one second semiconductor device 1300 may be paired and mounted on the corresponding portions of the interposer structure 1100S. However, the inventive concept is not limited thereto, and the first semiconductor device 1200 and the second semiconductor device 1300 may be paired/grouped in various combinations. For example, as illustrated in FIG. 7A, one second semiconductor device 1300 and four first semiconductor device 1200 may be grouped and mounted on the corresponding portions of the interposer structure 1100S. Accordingly, each of the initial chip packages PKGi may include a pair/group of the first semiconductor device 1200 and the second semiconductor device 1300, a corresponding portion of the interposer structure 1100S on which the pair/group is mounted, and a corresponding portion of the sealant structure 1500S that seals the pair/group.

Referring to FIG. 9B, after the first package structure PKGS1 is prepared, a lower metal layer structure 1420S may be formed on the upper surface of the first package structure PKGS1. The lower metal layer structure 1420S may include a plurality of lower metal layers corresponding to the initial chip packages PKGi. For example, the lower metal layer structure 1420S may be formed as a structure that completely covers the first package structure PKGS1 at a wafer level (e.g., on a wafer or on a wafer size substrate). On the other hand, as illustrated in FIG. 9B, the lower metal layer structure 1420S may have a multilayer structure corresponding to the lower metal layer 1420a of the intermediate heat dissipation plate 1400c in the semiconductor package 1000c of FIG. 5C. However, the structure of the lower metal layer structure 1420S is not limited thereto. For example, the lower metal layer structure 1420S may have a single layer structure, like the lower metal layer 1420 of the intermediate heat dissipation plate 1400 in the semiconductor package 1000 of FIG. 1. In some embodiments, the lower metal layer structure 1420S may be omitted. In this case, the intermediate metal layer may be formed directly on the upper surface of the first package structure PKGS1.

The lower metal layer structure 1420S may be formed through various processes, such as PVD, CVD, or plating. For example, in the method of manufacturing the system package, according to the present embodiment, the lower metal layer structure 1420S may be formed through sputtering of PVD. However, the process of forming the lower metal layer structure 1420S is not limited to sputtering. On the other hand, the layers of the lower metal layer structure 1420S may each include one of the various metal materials described above.

Referring to FIG. 9C, after the lower metal layer structure 1420S is formed, an intermediate metal layer 1440a may be formed on the lower metal layer structure 1420S. The intermediate metal layer 1440a may include only a protrusion, like the intermediate metal layer 1440a of the intermediate heat dissipation plate 1400b in the semiconductor package 1000b of FIG. 5C. For example, the intermediate metal layer 1440a may be formed of a protrusion pattern. The intermediate metal layer 1440a may have a shape as illustrated in FIGS. 2A to 2C and may be formed on a region corresponding to each of the initial chip packages PKGi. On the other hand, the structure of the intermediate metal layer 1440a is not limited to the structure that includes only the protrusion. For example, an intermediate metal layer having a structure including a base 1440B and a protrusion 1440P may be formed, like the structure of the intermediate metal layer 1440 of the semiconductor package 1000 of FIG. 1. The intermediate metal layer having the structure described above may completely cover the upper surface of the lower metal layer structure 1420S.

The intermediate metal layer 1440a may be formed through various patterning processes. For example, the intermediate metal layer 1440a may be formed by forming a metal material layer having a uniform thickness on the lower metal layer structure 1420S and etching the metal material layer through a photo process (e.g., a patterning process of a photosensitive layer) and an etching process. Alternatively, a photoresist (PR) pattern including trench patterns exposing the lower metal layer structure 1420S may be formed on the lower metal layer structure 1420S through a photo process (e.g., an exposure and development process). The intermediate metal layer 1440a may be formed by filling the trench patterns through a plating process.

Referring to FIG. 9D, after the intermediate metal layer 1440a is formed, an upper metal layer structure 1460S covering the lower metal layer structure 1420S and the intermediate metal layer 1440a with a uniform thickness may be formed. The upper metal layer structure 1460S may also include a plurality of upper metal layers corresponding to the initial chip packages PKGi. That is, the upper metal layer structure 1460S may be formed in a structure that completely covers the first package structure PKGS1 at a wafer level. The upper metal layer structure 1460S may be formed through various processes, such as PVD, CVD, or plating. For example, the upper metal layer structure 1460S may be formed through sputtering of PVD. However, the process of forming the upper metal layer structure 1460S is not limited to sputtering. On the other hand, the upper metal layer structure 1460S may include one of the various metal materials described above.

An intermediate heat dissipation plate structure 1400cS may be formed by forming the upper metal layer structure 1460S. In addition, a second package structure PKGS2 may be formed by forming the intermediate heat dissipation plate structure 1400cS. The second package structure PKGS2 may include a plurality of semiconductor packages PKG. Each of the semiconductor packages PKG may correspond to the semiconductor package 1000c of FIG. 5C.

However, the inventive concept is not limited thereto, and a heat dissipation plate structure of a different structure may be formed in the processes of FIGS. 9B to 9D. In this case, the second package structure PKGS2 may include semiconductor packages PKG of a different structure. For example, each of the semiconductor packages PKG may include any one of the semiconductor packages 1000, 1000a, 1000b, and 1000c of FIGS. 1, 5A, 5B, and 5D.

Referring to FIG. 9E, after the second package structure PKGS2 is formed, the second package structure PKGS2 may be attached to a ring mount device 4000. For example, as illustrated in FIG. 9E, the intermediate heat dissipation plate structure 1400cS on the rear side of the second package structure PKGS2 may be attached to the ring mount device 4000. For reference, the ring mount device 4000 may include a support ring and a dicing tape covering an open portion of the support ring. In FIG. 9E, only the dicing tape is illustrated for convenience, and the same applies to FIGS. 9F and 9G.

Referring to FIG. 9F, after the second package structure PKGS2 is attached to the ring mount device 4000, the carrier substrate 3000 may be removed from the second package structure PKGS2. When the carrier substrate 3000 is removed, an adhesive layer 3500 may also be removed.

Referring to FIG. 9G, a semiconductor package 1000c may be manufactured by singulating the second package structure PKGS2 through a dicing process. The semiconductor package 1000c may correspond to the semiconductor package 1000c of FIG. 5C. However, when the intermediate heat dissipation plate structure of the second package structure PKGS2 has a different structure, any one of the semiconductor packages 1000, 1000a, 1000b, and 1000d of FIGS. 1, 5A, 5B, and 5D may be manufactured through singulation of the second package structure PKGS2.

Referring to FIG. 9H, after the semiconductor package 1000c is manufactured, the semiconductor package 1000c may be mounted on a package substrate 1600 through first external connection terminals 1150. The package substrate 1600 may be the same as the package substrate described for the system package 2000 of FIG. 6A.

Referring to FIG. 9I, a heat dissipation structure 1700 may be stacked on the semiconductor package 1000c and the package substrate 1600. A system package 2000d may be manufactured by stacking the heat dissipation structure 1700. The heat dissipation structure 1700 may be the heat dissipation structure 1700 of the system package 2000 of FIG. 6A. Accordingly, the heat dissipation structure 1700 may include a top plate 1710 and a side plate 1730. However, the inventive concept is not limited thereto, and the heat dissipation structure 1700a of the system package 2000a of FIG. 6B may be applied to the system package 2000d.

The heat dissipation structure 1700 may be adhesively fixed to the semiconductor package 1000c through a TIM 1800. For example, the TIM 1800 may be arranged between the top plate 1710 of the heat dissipation structure 1700 and the intermediate heat dissipation plate 1400c, so that the heat dissipation structure 1700 may be adhesively fixed to the semiconductor package 1000c. In addition, the TIM 1800 may be maintained by being surrounded by a dam DAM on the upper surface of the intermediate heat dissipation plate 1400c, and thus, the TIM 1800 may be prevented from being pumped out in a TC reliability test. Accordingly, the heat dissipation capability and adhesive strength of the TIM 1800 may be increased. In addition, due to the increased adhesive strength of the TIM 1800, the warpage of the semiconductor package 1000c may be improved and defects such as non-wet/short of the first external connection terminal 1150 of the semiconductor package 1000c may be improved.

FIGS. 10A to 10C are cross-sectional views illustrating in more detail a process of manufacturing the first package structure of FIG. 9A. The following description is given with reference to FIGS. 10A to 10C together with FIG. 1, and contents provided above in the description of FIGS. 1 to 9G may be briefly described or omitted.

Referring to FIG. 10A, the process of manufacturing the first package structure may include mounting first semiconductor devices 1200 and second semiconductor devices 1300 on an interposer structure 1100S. The first semiconductor devices 1200 and the second semiconductor devices 1300 may be mounted on the interposer structure 1100S through connection terminals 300 and 1350 and underfill 1520. As illustrated, the first semiconductor devices 1200 and the second semiconductor devices 1300 may be paired/grouped and mounted on the interposer structure 1100S. Accordingly, the first semiconductor devices 1200 and the second semiconductor devices 1300, which are paired/grouped, may be arranged with a narrow gap, and the pairs/groups may be arranged from other pairs/groups with a wide gap there between. The underfill 1520 may surround and contact side surfaces of the first semiconductor devices 1200 and the second semiconductor devices 1300. For example, a plurality of first semiconductor devices 1200 and a plurality of second semiconductor devices 1300 may be arranged on the interposer structure 1100S to form a plurality of groups of semiconductor devices such that distances between immediate neighbor semiconductor devices 1200/1300 in each group are closer than distances between semiconductor devices 1200/1300 in different groups from each other, and each of the plurality of groups may include at least one of the plurality of first semiconductor devices 1200 and at least one of the plurality of second semiconductor devices 1300.

On the other hand, although not illustrated in FIG. 10A, the interposer structure 1100S may be fixed on a carrier substrate through an adhesive layer. In some embodiments, the interposer structure may have a thickness greater than a length of a through electrode, and a first external connection terminal may not be arranged on the lower surface of the interposer structure. In this case, the first external connection terminal may be arranged on the through electrode after a process of thinning the interposer structure.

Referring to FIG. 10B, after the first semiconductor devices 1200 and the second semiconductor devices 1300 are mounted, the first semiconductor devices 1200 and the second semiconductor devices 1300 on the interposer structure 1100S may be sealed with an initial sealant structure 1500Si. The initial sealant structure 1500Si may cover/contact side surfaces of the underfill 1520 and the upper surfaces of the first semiconductor devices 1200 and the second semiconductor devices 1300. In some embodiments, the underfill 1520 may cover/contact only a portion of the side surfaces of each of the first semiconductor devices 1200 and the second semiconductor devices 1300, and may expose the other portion of the side surfaces of each of the first semiconductor devices 1200 and the second semiconductor devices 1300. In this case, the initial sealant structure 1500Si may cover/contact the exposed side surfaces of each of the first semiconductor devices 1200 and the second semiconductor devices 1300. As the initial sealant structure 1500Si covers the upper surfaces of the first semiconductor devices 1200 and the second semiconductor devices 1300, the thickness of the initial sealant structure 1500Si may be greater than the thickness of the sealant structure 1500S of FIG. 9A.

Referring to FIG. 10C, a back-grinding process B/G may be performed to remove the upper portion of the initial sealant structure 1500Si. The upper surfaces of the first semiconductor devices 1200 and the second semiconductor devices 1300 may be exposed from the sealant structure 1500S through the back-grinding process B/G. In addition, the upper surfaces of the first semiconductor devices 1200 and the second semiconductor devices 1300 and the upper surface of the sealant structure 1500S may be coplanar and be formed on substantially the same plane. After the back-grinding process B/G for the initial sealant structure 1500Si, the first package structure PKGS1 of FIG. 9A may be manufactured.

According to an embodiment, a method of manufacturing a semiconductor package may include preparing a package structure including a plurality of initial chip packages, forming an intermediate heat dissipation plate structure on an upper surface of the package structure, forming a chip package by singulating the package structure and the intermediate heat dissipation plate structure, and mounting the chip package on a package substrate. The chip package may include an interposer, a first semiconductor device arranged on the interposer, a second semiconductor device spaced apart from the first semiconductor device on the interposer, and an intermediate heat dissipation plate that is a portion of the intermediate heat dissipation plate structure, is arranged on upper surfaces of the first semiconductor device and the second semiconductor device, and has a dam formed in an edge portion thereof. The forming of the intermediate heat dissipation plate structure may include forming a lower metal layer including at least one layer having a flat plate shape on an upper surface of the package structure, forming an intermediate metal layer including a protrusion constituting the dam on the lower metal layer, and forming an upper metal layer covering an upper surface of the intermediate metal layer with a uniform thickness. The intermediate heat dissipation plate may have a rectangular shape in a plan view. In the forming of the intermediate metal layer, the protrusion may have one of a continuous rectangular ring shape, a plurality of discrete L-shaped portions, or a plurality of linearly shaped portions. The protrusion may be formed in an edge portion of the intermediate heat dissipation plate through a patterning process. The method of manufacturing the semiconductor package may include attaching a heat dissipation structure on the chip package through a thermal interface material (TIM). The TIM may be surrounded by the dam.

The preparing of the package structure may include mounting a plurality of first semiconductor devices and a plurality of second semiconductor devices on an interposer structure including a plurality of interposers, sealing the plurality of first semiconductor devices and the plurality of second semiconductor devices with a sealant, and grinding an upper portion of the sealant so that upper surfaces of the plurality of first semiconductor devices and the plurality of second semiconductor devices are exposed.

The plurality of first semiconductor devices and the plurality of second semiconductor devices may be arranged on the interposer structure to form a plurality of groups of semiconductor devices such that distances between immediate neighbor semiconductor devices in each group are closer than distances between semiconductor devices in different groups from each other. Each of the plurality of groups may include at least one of the plurality of first semiconductor devices and at least one of the plurality of second semiconductor devices.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While the inventive concept has been particularly shown and described with reference to embodiments thereof, it will be understood that various changes in form and details may be made therein without departing from the spirit and scope of the following claims.

1. A semiconductor package comprising:
an interposer;
a first semiconductor device arranged on the interposer;
a second semiconductor device spaced apart from the first semiconductor device on the interposer; and
a heat dissipation plate arranged on upper surfaces of the first semiconductor device and the second semiconductor device and having a dam arranged in an edge portion of the heat dissipation plate.

2. The semiconductor package of claim 1, wherein
the heat dissipation plate has a rectangular flat plate shape, and
the dam has a rectangular ring shape and is arranged in an edge portion of an upper surface of the heat dissipation plate.

3. The semiconductor package of claim 1, wherein
the heat dissipation plate has a rectangular shape in a plan view, and
the dam is formed as a plurality of L-shaped portions, and each of the L-shaped portions is arranged adjacent to a corresponding one of four vertices of a rectangular upper surface of the heat dissipation plate.

4. The semiconductor package of claim 1, wherein
the heat dissipation plate has a rectangular shape, and
the dam has a plurality of linearly shaped portions, and each of the linearly shaped portions extends along a corresponding one of four sides of a rectangular upper surface of the heat dissipation plate.

5. The semiconductor package of claim 1, wherein the heat dissipation plate comprises:
a lower metal layer having a flat plate shape and comprising at least one layer;
an intermediate metal layer arranged on the lower metal layer and comprising a protrusion constituting the dam; and
an upper metal layer covering an upper surface of the intermediate metal layer with a uniform thickness.

6. The semiconductor package of claim 1, further comprising a sealant arranged between the interposer and the heat dissipation plate and sealing the first semiconductor device and the second semiconductor device.

7. The semiconductor package of claim 1, further comprising underfill filling a gap between the first semiconductor device and the interposer and between the second semiconductor device and the interposer,
wherein the underfill covers at least a portion of side surfaces of the first semiconductor device and the second semiconductor device.

8. The semiconductor package of claim 1, wherein
the first semiconductor device comprises a high bandwidth memory (HBM) package, and
the second semiconductor device comprises a logic chip.

9. The semiconductor package of claim 1, wherein the interposer is a silicon (Si)-interposer or a redistribution interposer with a Si-bridge.

10. A semiconductor package comprising:
a package substrate;
a chip package arranged on the package substrate; and
a heat dissipation structure arranged on the chip package,
wherein the chip package comprises:
an interposer;
a first semiconductor device arranged on the interposer;
a second semiconductor device arranged on the interposer and spaced apart from the first semiconductor device;
an intermediate heat dissipation plate arranged on upper surfaces of the first semiconductor device and the second semiconductor device and having a dam arranged along an edge portion thereof; and
a sealant arranged between the interposer and the intermediate heat dissipation plate and sealing the first semiconductor device and the second semiconductor device.

11. The semiconductor package of claim 10, wherein
the intermediate heat dissipation plate has a rectangular shape in a plan view, and
the dam has one of a rectangular ring shape, an L-shape, or a straight line shape and is arranged in an edge portion of an upper surface of the intermediate heat dissipation plate.

12. The semiconductor package of claim 10, wherein the intermediate heat dissipation plate comprises:
a lower metal layer having a flat plate shape and comprising at least one layer;
an intermediate metal layer arranged on the lower metal layer and comprising a protrusion constituting the dam; and
an upper metal layer covering an upper surface of the intermediate metal layer with a uniform thickness.

13. The semiconductor package of claim 10, further comprising underfill filling a gap between the first semiconductor device and the interposer and between the second semiconductor device and the interposer, wherein
the underfill covers at least a portion of side surfaces of the first semiconductor device and the second semiconductor device, and
the sealant covers the underfill.

14. The semiconductor package of claim 10, wherein
the interposer comprises a silicon (Si)-interposer or a redistribution interposer with a Si-bridge,
the first semiconductor device comprises a high bandwidth memory (HBM) package, and
the second semiconductor device comprises a logic chip.

15. The semiconductor package of claim 10, wherein
the heat dissipation structure is bonded to an upper surface of the chip package through a thermal interface material (TIM), and
the TIM is surrounded by the dam.

16. The semiconductor package of claim 15, wherein the heat dissipation structure comprises one of:
a first structure comprising a top plate bonded to the TIM and a side plate extending vertically downward from the top plate, wherein the side plate is in contact with an upper surface of the package substrate, or
a second structure comprising a heat dissipation plate bonded to the TIM and a stiffener supporting the heat dissipation plate, wherein the stiffener is in contact with the upper surface of the package substrate.

17. A semiconductor package comprising:
a package substrate;
a chip package arranged on the package substrate;
a heat dissipation structure arranged on the chip package; and
a thermal interface material (TIM) arranged between the chip package and the heat dissipation structure,
wherein the chip package comprises:
an interposer;
a first semiconductor device arranged on the interposer;
a second semiconductor device spaced apart from the first semiconductor device on the interposer; and
an intermediate heat dissipation plate arranged on upper surfaces of the first semiconductor device and the second semiconductor device and having a dam surrounding the TIM in an edge portion thereof.

18. The semiconductor package of claim 17, wherein
the intermediate heat dissipation plate has a rectangular shape in a plan view, and
the dam is formed as one of a continuous rectangular ring shape, a plurality of discrete L-shaped portions, or a plurality of linearly shaped portions and is arranged in an edge portion of an upper surface of the intermediate heat dissipation plate.

19. The semiconductor package of claim 17, wherein the intermediate heat dissipation plate comprises:
a lower metal layer having a flat plate shape and comprising at least one layer;
an intermediate metal layer arranged on the lower metal layer and comprising a protrusion constituting the dam; and
an upper metal layer covering an upper surface of the intermediate metal layer with a uniform thickness.

20. The semiconductor package of claim 17, wherein
the interposer comprises a silicon (Si)-interposer or a redistribution interposer with a Si-bridge,
the first semiconductor device comprises a high bandwidth memory (HBM) package, and
the second semiconductor device comprises a logic chip.

21-25. (canceled)
